(19) United States
(12) Patent Application Publication
(10) Pub. No.: US 2015/0094989 A1
(43) Pub. Date: Apr. 2, 2015

(54) SYSTEM AND METHOD FOR MONITORING GEOTHERMAL HEAT TRANSFER SYSTEM PERFORMANCE

(71) Applicants: Denis Lazare Collet, Tivoli, NY (US); Andrew Smallridge, Canning Vale, WA (US)

(72) Inventors: Denis Lazare Collet, Tivoli, NY (US); Andrew Smallridge, Canning Vale, WA (US)

(21) Appl. No.: 14/044,613

(22) Filed: Oct. 2, 2013

(51) Int. Cl. G01M 99/00; G01L 7/00; G01K 13/00; G01F 1/00; F24J 3/08; G01R 21/00

(52) U.S. Cl. CPC G01M 99/008; F24J 3/08; G01R 21/00; G01K 13/00; G01F 1/00; G01L 7/00
USPC 702/188

(57) ABSTRACT

A remote monitoring apparatus for geothermal heat transfer systems creates stores and transfers a structured time-stamped database of system parameters useful in determining efficiency, in diagnosing problems remotely and which is not only robust but which is reconfigurable from a remote location. The system of the present invention provides geothermal system installers with a significant tool for the purposes of client maintenance.

### TECHNICAL FIELD

The present invention is generally directed to the monitoring of geothermal energy systems. More particularly, the present invention is directed to remote sensing of heating systems which employ ground based sources for heating and cooling. Even more particularly, the present invention is directed to systems for use by heating contractors to monitor the performance of installed system and to be able to perform remote diagnostic analyses, and especially to enable the prevention of predicted/predictable failures or reduction in performance.

### BACKGROUND OF THE INVENTION

Geothermal energy systems for household or commercial heating and cooling provide significant advantages and offer significant promise for reduction in energy demand. These systems take advantage of relatively constant subterranean temperatures which are employable as a thermodynamic assist to winter heating and to summer cooling. (In the southern hemisphere the terms “winter” and “summer” may carry with them different meanings; the meanings employed herein are directed to northern hemisphere descriptions; however, nothing contained herein limits the use of the present invention in any particular hemisphere.)

Geothermal systems are of several different types. On a general level, such systems can be “open loop” systems or “closed loop” systems. In an open loop system an in ground well is provided which accesses subterranean groundwater sources. In open loop systems, water is extracted from the well and water flow from the geothermal heating/cooling system may be dumped back into the well typically (though not required to be) from a location at or near ground level or into a “dry well” located at a distance from the ground water source. This latter arrangement is also sometimes referred to as “pump and dump.” Open loop systems are easier to construct but they have the disadvantage that the water stream may also contain particulate matter and other compounds which tend to be dissolved in the flow. Filters ameliorate this problem but introduce an added complexity along with a desire to monitor pressure drops across such filters as a mechanism for determining whether or not they have been clogged and/or the degree to which they are clogged. In one aspect of the present invention, return flow is selectively directed either to the well which is the source of ground water or to a separate dry well, as a function of water temperature.

Geothermal systems may also fall into the category of closed loop systems. There are, in general, five types of closed loop systems: (1) a horizontal loop or loops; (2) a vertical loop or loops; (3) closed conduit(s) disposed in a nearby pond; (4) loop(s) placed in accordance with radial or directional drilling techniques; and (5) buried tanks. In these systems an elongated U-shaped pipe or set of pipes is disposed into a bored well. This well is then filled with material which enhances thermal conductivity between the pipes and the ground. Closed loop systems do not suffer the disadvantage of entraining particulate and dissolved matter in the water flow. Close loop systems typically include a plurality of U-shaped pipes disposed at the distal positions (for example, 25 feet or more) at the surface. This arrangement readily permits either serial or parallel connections to be made with these U-shaped pipes. It is furthermore noted that in closed loop systems, other piping arrangements may be employed. For example, piping may be disposed in a relatively shallow trench or series of trenches. Piping may also be disposed in a single trench in a coiled configuration.

In any event, it is noted that the present invention is usable with any of these systems and with other heating and/or cooling systems as well. In particular, it is seen that the present invention is capable of determining overall system performance via measurements of water temperature and flow rate wherein the water temperature is determined as it leaves the “well” and as it flows back into the well. Here, the use of the term “well” refers to both the open loop and close loop categories of geothermal systems.

Geothermal systems themselves often have more than one stage of operation. Such a system may be operating in a relatively low-power mode or 1^{st} stage. Switching to a higher power mode, or next stage of operation, is based on its ability to satisfy the demand for heating or cooling depending on a number of factors. These factors, including thermostat settings and the response time of the system to satisfy the demand, account for most of the conditions affecting the stages of operation. For example, the ambient room temperature may be 55° F. [13.8° C.] with a thermostat setting of 55° F. the system may be off. If the thermostat is reset to 68° F. the system may switch from a 1^{st} stage moving through additional stages up to 3^{rd} stage heating mode to satisfy the new demand as quickly as possible. The cycling time governing transition from one stage to the next is based on system logic programmed into the thermostat and geothermal system. Accordingly, in many geothermal system installations a secondary or tertiary backup heating or cooling source is provided. In practical situations there is almost always a secondary or tertiary heating mechanism which is activated when it is determined that the heating load is beyond the capabilities of the system. In such cases, the backup heating supply is typically provided by electrical resistance heating mechanisms. However, fossil fueled mechanisms are also employed to serve this backup functionality.

Clearly, one of the desired aspects of having a geothermal system installed is improvement in energy efficiency and utilization. However, capabilities for performing geothermal system analysis to determine the efficiency level have not been deployed. This performance is generally referred to by the term “coefficient of performance.” The present invention is capable of determining of this system parameter on an ongoing basis. The present invention is also capable of monitoring a plurality of parameters that are useful in diagnosing problems that are peculiar to geothermal systems.

In particular, is noted that in at least one instance in which an open loop system was operating, the return of cooled water to the well resulted in an unstable feedback condition in which the well temperature kept getting cooler and cooler until flow was interrupted by freezing conditions. In this particular situation, it was determined that return of system water to the open loop well was the problem. More particularly, it is noted that this problem was solved by returning the system water to a separate dry well. Nonetheless, this problem led to the recognition that the monitoring of temperature conditions in a geothermal system was highly desirable.

The present invention provides remote monitoring of a number of useful parameters in an installed geothermal system. Remote monitoring is desirable from a number of perspectives. For example, a system which provides alerts indicating the existence of a system state that is either problematic or leading to a problem, provides a mechanism for the installer of a geothermal system to provide maintenance before a service interruption. Furthermore, remote monitoring of a number of these parameters is also useful as input to a logic engine which is capable of performing system diagnostics. It may not be the case that a problem exists or is pending but it may happen to be the case that over time it is seen that overall system performance is deteriorating. Such analyses are useful in providing diagnostic and maintenance information indicate a particular course of action for performance improvement. This is particularly useful in heating and cooling installations based upon geothermal systems since end users of such systems typically purchase them for the principal reason that they do provide improved performance and reduce energy costs.

From the point of view of an installer of geothermal systems, the present invention provides a mechanism in which the geographical area in which the business operates may be significantly extended. In particular, the present invention, through its remote monitoring capabilities, is capable of not only preventing outages but is also capable of providing maintenance information to the installer's staff.

In designing remote monitoring and control systems for geothermal systems, several important factors and circumstances ought to be considered. In short, while it is known that installation of such systems requires the deployment of various sensors and a collection of mechanisms for returning the data to a location from which it may be accessed and used, it is important that the installation procedure be such that once physical devices are in place, that assignment of the various devices and sensors also be such that it too can be processed and handled from a remote location. In particular, it is noted that the present invention provides a mechanism for remotely assigning various communication ports to various ones of a desired set of devices. Furthermore, in this regard it is to be particularly noted that the configurations present in any given installation are going to be extremely numerous. This makes so-called field configuration difficult. However, because the present invention is connected to an external database via the Internet (or any other convenient communication modality) an installer of the present invention is capable of installation and configuration on site simply through the use of a laptop (or other mobile communication device) which is capable of an Internet (or other) connection.

While the present invention encompasses various methods for the wired and wireless transmission of data back to a remote system for diagnoses, service and repair, the Internet is a preferred modality. However, as is well known, Internet connectivity is not guaranteed 100% of the time. Hence, any monitoring system should be able to accommodate such outages. This is also true in circumstances in which connection to a remote location is via a cellular service since these services too can experience outages especially in the wake of severe storm systems. Accordingly, practical systems for geothermal system monitoring should include a mechanism for on-site storage of data together with a mechanism for retrieving that data when service is restored. Moreover, data retrieval should be possible as either a “push” from the remote site or as a “pull” from the server.

It is noted that geothermal systems are unlike other heating and cooling systems in several aspects. In particular, these aspects arise out of the fact that these systems are closely coupled with subterranean or ground conditions. As discussed elsewhere herein, it is again emphasized that these systems are really more accurately described as being ground source heat pumps as opposed to true “geothermal” systems. For example, as indicated above, conditions can arise when groundwater becomes too cold for use (open loop system problem). Additionally, the various components of a geothermal system may experience activation at times which do not optimally promote energy efficiency. For example, the valves that are stuck in partially open or partially closed conditions can negatively impact the coefficient of performance. Knowledge of such circumstances is not immediately if ever available to the end customer.

In typical geothermal systems, the installer provides certain warranties with respect to system performance and operation. If problems are experienced following initial system installation, as they often are, the system installer is saddled with the task of providing on-site service. This is often expensive and time-consuming. It also negatively impacts geothermal customers in that this expense is at some level or some degree passed on to the customer either as part of the initial sale or as part of an ongoing service contract. It is therefore seen to be desirable to provide remote monitoring capabilities to catch problems before they occur and to diagnose trouble conditions before dispatching a repair crew. The present invention provides this capability and more. Even more particularly, the present invention provides the capability of system monitoring by an end using customer.

One of the other aspects that is present in the design of systems which are intended to monitor the performance of geothermal heating and cooling systems is the fact that a number of these geothermal heating and cooling systems are already in existence. Accordingly, desirable geothermal heating and cooling systems include a capability in which the monitoring systems are capable of being retrofitted to existing geothermal systems.

Other aspects relating to geothermal energy systems includes the fact that these systems are more complex than conventional heating and cooling systems and concomitantly bring with them increased service issues. Since geothermal energy systems are energy efficient two benefits result: (1) a reduced heating cost for the homeowner; and (2) a reduction in the emission of green house gasses. However, their increased complexity is offset by higher installation and service costs. Accordingly, in order to achieve the two benefits stated above, it is desirable to keep the service and maintenance costs low. These costs can escalate if there are multiple service callbacks during a period of time covered by warrantees on the system. This problem of escalating costs is exacerbated by the fact that there is no available way of remotely determining whether or not a geothermal system is operating efficiently. Furthermore, the determination of efficiency is a measurement which is best known over an extended period of time (weeks or months) and during a variety of external weather conditions (temperature, humidity and wind). Simply looking at electrical power utilization does not provide any kind of reliable indicator as to the level of geothermal system performance since that is only the input part of the energy equation. Much more information is required.

Furthermore, it is to be particularly noted that, while long-term performance evaluations are highly desirable, instantaneous or shorter-term parameter determination is also desirable as a mechanism for providing system alerts and emergency notifications. In many cases such information can save the expense of an onsite service call. Additionally, intermittent problems can be extremely difficult to diagnose and to re-create. Accordingly, the existence of a database containing historically accurate information on system parameters is highly desirable. Without continuous system monitoring, it is difficult to proactively determine the cause of a failure. It is therefore very desirable to have a database in which diagnostically indicative events have been recorded. Furthermore, it is desirable to have such a database available in an online fashion accessible over the Internet or by some other mechanism. Without historical information about the system, it is difficult to know if an upgrade is meeting expectations as compared to advertised improvement(s).

Additional considerations are also important in the design and implementation of a geothermal monitoring system. In particular, it is noted that the system should be designed to be operable with any number of different geothermal system variants. Different systems will have different sets of conduits and different sets of control valves and power levels. A monitoring system should be capable of being used with a large variety of different geothermal systems. Furthermore, the desired monitoring system should exhibit the quality of being expandable. For example, different heating and cooling control zones may come into being at a time after installation of the geothermal system and or after the installation of a monitoring system such as the one described herein.

The present application refers to the heating systems to which the invention is directed as being “geothermal systems.” This is correct as it relates to the terminology that has come to be employed in common parlance. However, it is noted that in a more technically accurate parlance, geothermal systems typically refer to systems which use extracted heat from the earth, typically near volcanic or volcano-like sources such as those found in Iceland or around Yellowstone National Park and in other locales. The systems to which the present invention are directed are those that are more accurately referred to as ground source heat pumps.

From the above, it is therefore seen that there exists a need in the art to overcome the deficiencies and limitations described herein and above.

### SUMMARY OF THE INVENTION

The shortcomings of the prior art are overcome and additional advantages are provided through the use of a flexible, reconfigurable, remote geothermal heat transfer system monitoring apparatus which provides remote access for purposes of analysis, diagnosis and control. As used herein, the terms “remote” or “remotely” refer to the fact that in at least one embodiment of the present invention there are two components which communicate with one another. Each is remote to the other and whichever one is remote is clear from the context. However, when on-site diagnoses of the geothermal system and the monitoring system occur, the remoteness is relative and may be measured in feet, as opposed to miles.

In one aspect of the present invention, there is provided a system for monitoring the operational status of a geothermal heat transfer system in which there are deployed a plurality of sensors and/or information transducers. These transducers include at least temperature sensors for determining the difference in water temperature into an out of the ground source. Additionally, there is a sensor for flow rate which, together with the other sensors, provides a mechanism for computing thermal transfer. The monitoring system includes a data processing apparatus which polls the sensors and associates collected data with a timestamp. Data is gathered and stored locally and periodically transmitted to a remote location via a communications mechanism. A data processor at the remote location is used to determine geothermal system efficiency using the transmitted data. Local storage of data is critical for providing a robust monitoring system which is capable of collecting and maintaining system information in the face of communication failures (such as an Internet outage). Such failures are endemic in various types of natural disaster situations. The present invention also preferably includes a function in which it is periodically determined at the server that data is being transmitted. In short, the server is preferably capable of checking for a “heartbeat” to provide assurance that the monitoring function is operational. Failure to detect a heartbeat from the remote location is usable to provide an alerting function. In other aspects of this embodiment, information is also obtained from various sensors and devices which serve to provide an indication of system state (valve position, fan operation, temperature, temperature settings, stage, electrical power).

In accordance with another embodiment of the present invention there is provided a data acquisition module which includes a microprocessor having local storage for instructions and data. The microprocessor is coupled to a real-time clock which provides a capability for associating a timestamp with gathered data. There are ports in the data acquisition module for receipt of temperature information and flow rate information. Non-volatile storage is used to contain a database of time stamped information from the ports. The database is generated under control of instructions carried out by the microprocessor.

In yet another embodiment of the present invention a monitoring system for a geothermal heat transfer apparatus comprises a remote processor which is capable of generating time stamped records which are indicative of operating parameters for the geothermal system. A central hosting facility is linked to the remote processor and contains a database of the records that are received from the remote processor. Lastly, in this particular embodiment, there is a mechanism which displays a facsimile image of a conventional geothermal system along with indicators of the operating parameters that that are derived from the database.

In yet another embodiment of the present invention there is provided a data processing system board which is capable of communicating data to a remote location. This system board is used in conjunction with a distinct connector board which is pluggable into the data processing system board and which has conductors thereon for connection to various information transducers associated with a geothermal heat transfer system, such transducers including temperature sensors, flow rate meters, electrical power indicators, thermostats, power meters, valve control indicators and similar information transducers as would be employed in geothermal heat transfer systems.

There are several aspects to the present invention. From one aspect, it is a hardware device intended to be used with a system of sensors which monitor the parameters associated with a geothermal heating and or cooling system. From another perspective it is the aforementioned data gathering collecting formatting and transmitting hardware together with a system of sensors which provide remote monitoring of functionality for a geothermal heating or cooling system. This functionality preferably includes system state, not just ground water thermal transfer data. From another perspective, the present invention provides a method for providing a service to geothermal system users. It is also a method for providing increased geographical coverage and revenue streams for geothermal system installers. From yet another perspective the present invention provides a method for controlling certain devices which are typically found in geothermal systems such as fans, pumps and thermostats.

In broad terms, the present invention is a geothermal heat transfer monitoring system which is capable of remote access and which is capable of being configured remotely. The present invention is particularly useful for installers and maintainers of such systems as a mechanism for improved service, cost reduction and efficiency monitoring. The present invention is also useful for owners to control the operation of the geothermal heating and cooling system remotely, including the ability to start and stop the geothermal heating and cooling system. This capability is useful to minimize the energy utilization for a premise that is unoccupied for an extended period of time. Being able to start/stop the geothermal heating and cooling system and being able to adjust the user set points provides greater flexibility and enhances the customer experience.

Accordingly, it is an object of the present invention to be able to remotely monitor the operating characteristics of a geothermal heat transfer system.

It is another object of the present invention to provide a remote monitoring system which is capable of being configured and reconfigured from a remote location.

It is yet another object of the present invention to provide a mechanism for the continual monitoring of geothermal heat transfer system performance.

It is a still further object of the present invention to provide a method for the remote diagnoses of problems befalling a geothermal heat transfer system

It is still another object of the present invention to provide on-screen diagnostic capabilities in a fashion which is representative of the geothermal heat transfer system itself.

It is a still further object of the present invention to provide a remote monitoring capability for a geothermal heat transfer system in which a system board is provided with a daughter connector board in a fashion which facilitates easy replacement of either one and which also facilitates easy modifications of sensor connections and which also facilitates easy expansion of the monitoring system for the inclusion of addition sensors and sensor types.

It is also an object of the present invention to provide a business service for use by geothermal system installers which provides a revenue stream and which also enhances customer service especially service being carried out under warranty conditions.

Lastly, but not limited hereto, it is an even further object of the present invention to provide users of geothermal heating and cooling systems with improved service, rapid diagnoses, condition alerts, notifications of problems, easy scheduling of maintenance, tracking of performance and prompt service by qualified personnel who can service problems having a heads up awareness of a problem situation.

Additional features and advantages are realized through the techniques of the present invention. Other embodiments and aspects of the invention are described in detail herein and are considered a part of the claimed invention. The recitation herein of desirable objects which are met by various embodiments of the present invention is not meant to imply or suggest that any or all of these objects are present as essential features, either individually or collectively, in the most general embodiment of the present invention or in any of its more specific embodiments.

### BRIEF DESCRIPTION OF THE DRAWINGS

The subject matter which is regarded as the invention is particularly pointed out and distinctly claimed in the concluding portion of the specification. The invention, however, both as to organization and method of practice, together with the further objects and advantages thereof, may best be understood by reference to the following description taken in connection with the accompanying drawings in which:

FIG. 1 is a block diagram illustrating the overall structure and distribution of the present invention;

FIG. 2 is a block diagram illustrating the overall structure of a typical geothermal system contemplated for use with the present invention;

FIG. 3 is a block diagram illustrating the in ground aspects of one embodiment of an open loop geothermal heating and cooling system;

FIG. 4 is a block diagram illustrating the overall structure of the data gathering, instruction processing, formatting, transmission and communication portion used in conjunction with the present invention;

FIG. 5 is a block diagram illustrating the overall structure of the data acquisition module shown in FIG. 4;

FIG. 6 is a block diagram illustrating the various functional components carried out by the data acquisition module shown in FIGS. 4 and 5;

FIG. 7 is a diagram illustrating the placement of various circuit components disposed on a parent printed circuit board used to embody the various aspects of the present invention;

FIG. 8A is a view similar to FIG. 7 except more particularly showing a connector board intended to act as a “daughter” circuit board whose function is to provide connections for various ones of the sensors (information transducers) employed in the monitoring of a geothermal heating and or cooling system;

FIG. 8B is a view which illustrates to the placement and relationship of the printed circuit board of FIG. 7 together with the daughter/connector board shown in FIG. 8B.

FIG. 9 describes the data structure of a generic form of “datagram” employed as a communication format and more particularly illustrates the structure of data which is transmitted from a remote location, typically via the Internet, to a web server which is accessible to a geothermal system installer or service entity;

FIG. 10 is a diagram illustrating the flow of data from a remote location to a point where it is accessed (or accessible) by service or other personnel and which further indicates what data is processed by various components of the present invention;

FIG. 11 is a plurality of graphically displayed information generated from the database generated by operation of the present invention and more particularly illustrates various aspects contributing to system performance over a relatively extended period of time;

FIG. 12 is a view similar to FIG. 11 but which more particularly illustrates the behavior of the same system over a much shorter time span;

FIG. 13 is a chart of energy comparisons provided over a selected period of time, on the order of hours, days or months;

FIG. 14 is a block diagram illustrating the use of the database generated for any given installation by the present invention in conjunction with logic systems which analyze this data to provide either an alert or more detailed diagnostic information;

FIG. 15 is an illustration of a typical display screen showing the various parameter values present at a given time in a geothermal system being monitored by the present invention;

FIG. 16 is a display of the main computer screen associated with the interaction of a remote service person wherein that person is empowered to access general information, alarms that may have been triggered, system status and/or system performance;

FIG. 17 is a chart versus time illustrating the percentage of time spent in various heating stages (high power, low-power, emergency backup, on/off);

FIG. 18 is a view similar to FIG. 17 except taken over a shorter (by hour) period of time as a mechanism for providing diagnostic indications of performance and/or problems;

FIG. 19 is a view of a computer screen employed in conjunction with the present invention where herein “maintenance” refers to the configuration of an installed system and may provide an indication for a maintenance alert;

FIG. 20 is a view of a computer screen employed in the present invention when it is desired to modify the configuration settings of the invention;

FIG. 21 is a view of a computer screen at the time of system set up or system configuration or reconfiguration;

FIG. 22 is a view of a computer screen which is accessed when the corresponding selection is made from the computer screen shown in FIG. 21;

FIG. 23 is a view of a computer screen which is accessed when the corresponding selection is made from the computer screen shown in FIG. 21;

FIG. 24 is a view of a computer screen which is accessed during the modification of an existing system installation; and

FIG. 25 is a view of a computer screen which ensues from access points seen on the computer screen shown in FIG. 24;

### DETAILED DESCRIPTION

The present invention possesses several different facets not all of which may be present in a single embodiment. The present invention encompasses devices, methods of operation, data structures, methods of business operation and various combinations of these. From an overall or global perspective, the present invention provides a system for monitoring geothermal heating and cooling systems. The present invention provides mechanisms for capturing and controlling information that flows from various devices attached to a geothermal system. In particular, the geothermal system in question is typically one that is located at a remote location. As used herein, the term “remote” may also refer to the on-site retrieval of stored information and various control functionality; in particular, the present invention provides a mechanism for service personnel to be present at the site of the geothermal system with a laptop computer, smart phone, or other mobile devices capable of access to the monitoring system; it is also possible for the home owner or user to have some access to the monitoring system via his/her home computer, smart phone, or other mobile device. In any event, the information collected by the present invention is accessible from the remote location as well. The data gathered is time-stamped information collected in a data structure for temporary storage and for transmission to a host server which preferentially includes intelligent knowledge-based processing mechanisms for the generation of alert information and performance information. In particular, in order to measure a coefficient of performance (COP) for the remote geothermal system, a well inlet temperature and a well outlet temperature are sensed and recorded along with fluid flow rate. This information provides a basis for determining the amount and rate of energy flow from the ground source employed. In order to compute COP, however, it is necessary to determine electrical energy usage (kilowatt-hours, abbreviated as “kwh,” a measure of energy usage). It is also desired to know the state that the system is in. This includes such information as “fan on/fan off,” “valve open/valve closed,” “stage 1/stage 2,” etc.

The sensed data is collected locally and is transmitted to a central hosting facility either on a periodic basis or upon control directed from a console monitored by a geothermal system installer. Additionally, the data is also accessible by the homeowner or end-user customer, typically via his or her own Internet access.

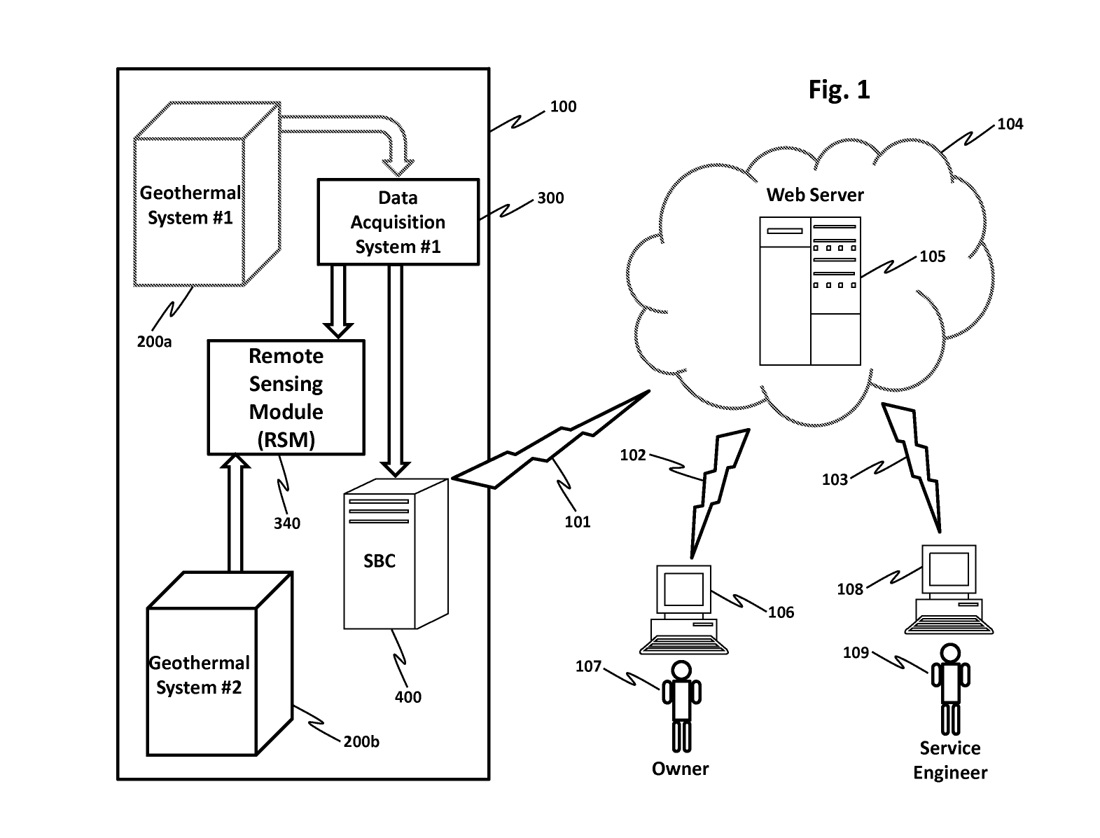

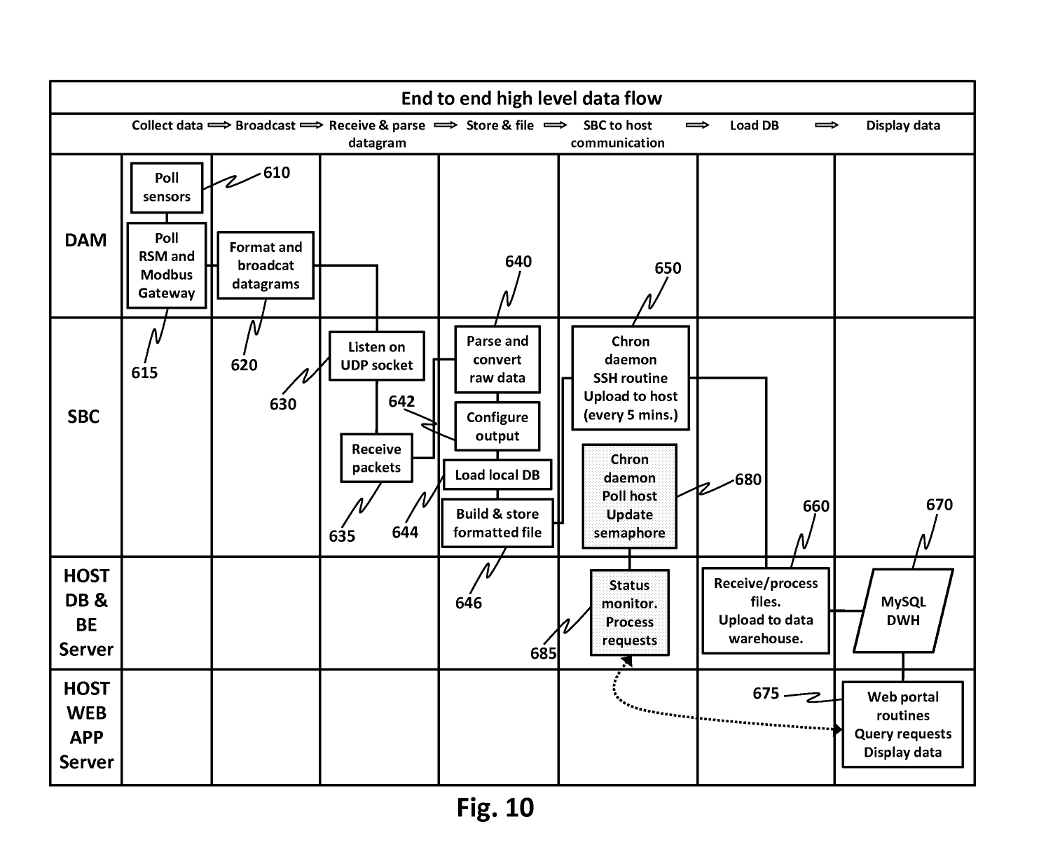

With this background in mind, it is useful to consider the various figures provided herein. In particular, it is seen that FIG. 1 provides an overall illustration of the components employed in the present invention. In particular, remote location 100 (a home, a business or other commercial establishment) is seen to possess geothermal systems 200a and 200b. Two such systems are illustrated since many commercial establishments have multiple geothermal systems installed. These may be installed in separate buildings or in different zones in the same building. The present monitoring system provides a single data acquisition module 300. System 200a supplies data to SBC 400 via DAM 350. System 200b supplies data to Remote Sensing Module 340 which sends its date to DAM 350. Data acquisition module 400 communicates with processor which is herein designated as Single Board Computer (SBC) 400. Some of the functions of SBC 400 are more particularly discussed below and are more particularly illustrated in FIG. 10. The term “single board computer” is a term of art meaning “a single-board computer (SBC) is a complete computer built on a single circuit board, with microprocessor(s), memory, input/output (I/O) and other features required of a functional computer.” (As per Wikipedia.)

One of the roles of SBC 400 is the normalization, formatting and transmission of captured data to a central hosting facility illustrated in FIG. 1 as Web server 105. Server 105 is a server that is typically established, controlled and monitored by a geothermal system installer (or their employee) 109 via computing device 108. Device 108 is typically implemented as a laptop or desktop computer. However, it may also comprise a tablet or smart phone-computing device. Although Web server 105 is primarily intended for access by service engineer 109, it is also accessible by the homeowner or end-user 107 by means of his or her own Internet connection device 106. Arrows 101, 102 and 103 are intended to indicate an Internet or other wired or wireless connection. In the present invention, the Internet is the preferable mechanism for providing such connections due to its low cost, familiarity of use and its relatively ubiquitous character. Other mechanisms for communication may also be employed in the present invention without departing from its intended scope. Cloud 104 is intended to indicate that Web server 105 is accessible via the Internet.

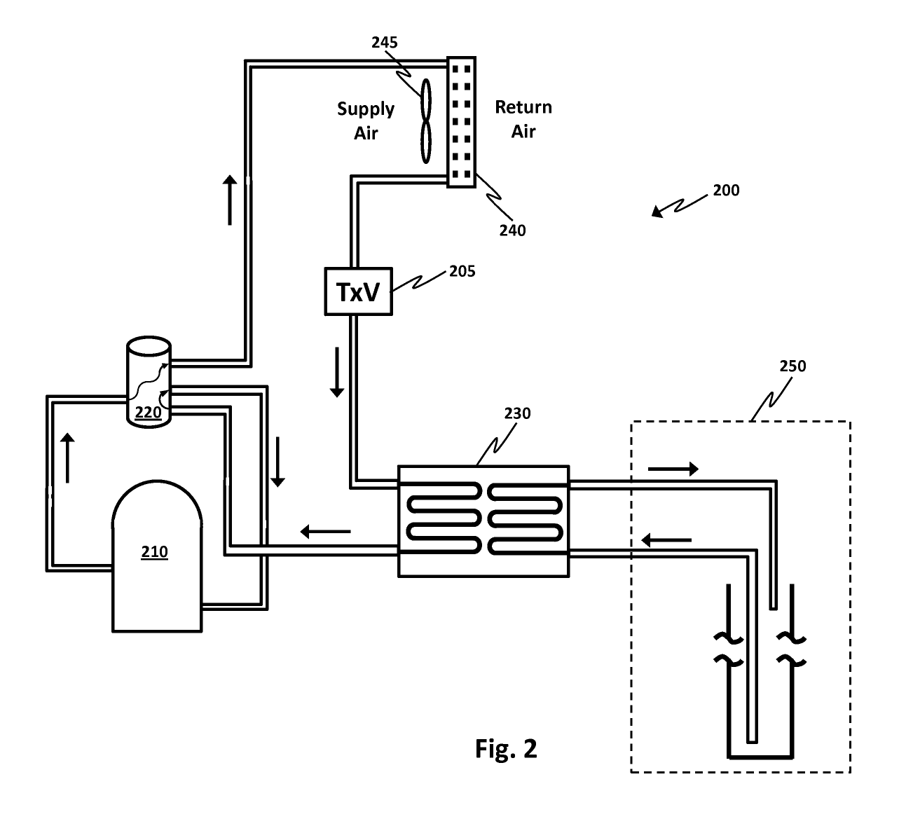

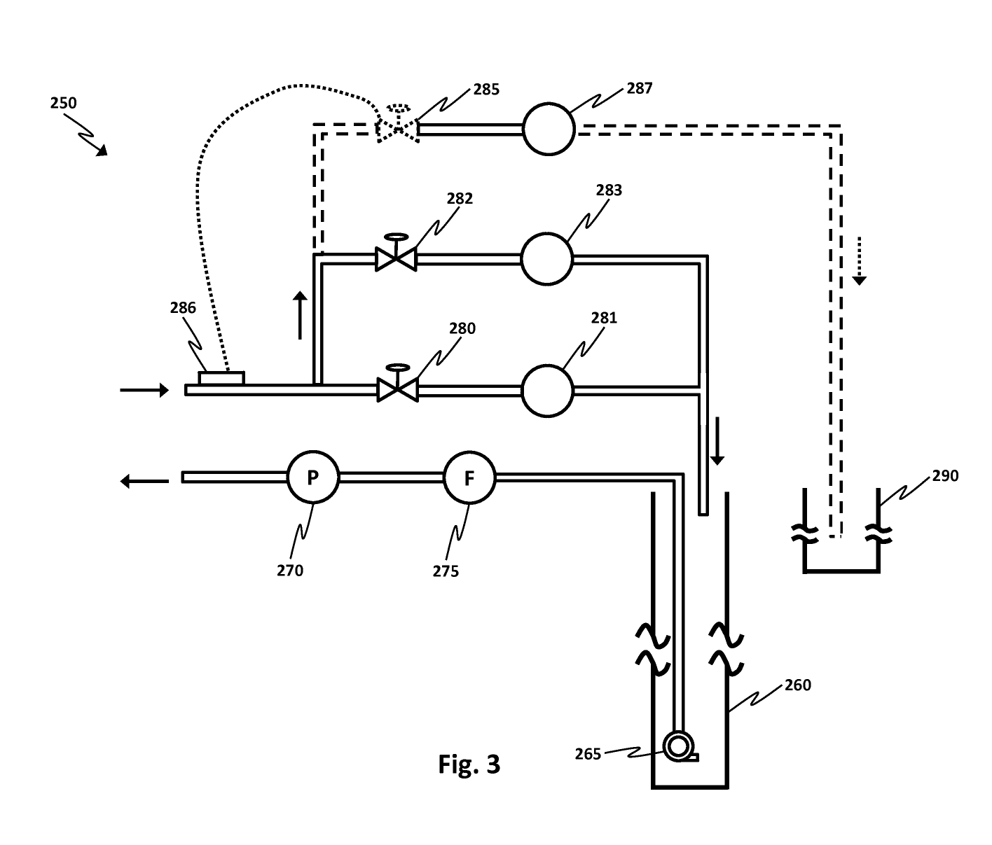

Understanding the operation of the present invention is facilitated by understanding the general operation of a ground sourced or geothermal heating and cooling system. In particular, system 200 in FIG. 2 includes well portion 250 which is shown in greater detail in FIG. 3. The particular well illustrated in FIGS. 2 and 3 is an open loop well. Closed loop wells have a design such as that described more particularly above. The salient aspect of a well portion of a geothermal system is that there is a flow of coolant fluid into and out of the well. The inlet and outlet temperatures associated with this fluid are important parameters in determining a coefficient of performance for a geothermal system. Coolant from well 250 is supplied to heat exchanger 230.

In the other loop flow through heat exchanger 230, the fluid is a coolant. Typically this coolant is a refrigerant type fluid such as Freon or other fluorochlorocarbon. Such materials are to be distinguished from the less desirable chlorofluorocarbons. In any event, such coolants are conventional parts of geothermally based heat pumps and heat pump systems.

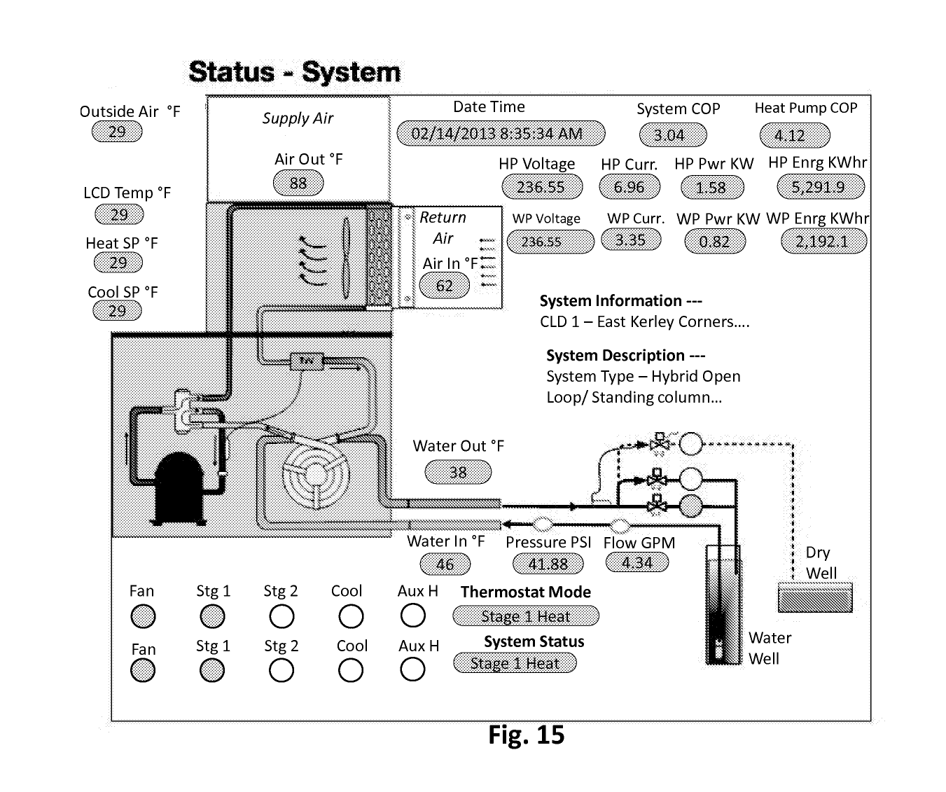

The core of a geothermal system 200 is compressor 210. Also of importance in FIG. 2 is the presence of reversing valve 220. As shown, this valve is positioned so that the flow of coolant is such as to provide heat to a particular spatial volume. In particular, compressor 210 compresses the coolant fluid and in so doing ads heat to the fluid. The heated coolant then flows through air to liquid heat exchanger 240. Fan to 45 provides a flow of room air to heat exchanger 240 and thus heats the room air. Coolant and then continues to flow in the indicated conduit through expansion valve 205. In doing so, the coolant fluid expands and is thus cooled. The cooled coolant then passes through heat exchanger 230 from which the coolant picks up heat. This heat is acquired because, at this point, the coolant temperature is lower than the groundwater temperature from well 250. This ground sourced heat is added at a point in the cycle which thus enables it to contribute to heat energy added to a room supplied with air from fan 245. It is to be particularly noted that there is an indication of fluid flow through reversing valve 220. The flow indicated is the flow that is present during a heating operation. In the summer when cooling is desired, flow in this valve is modified so that compressed fluid flows first through heat exchanger 230 and thence through expansion valve 205. It is thus seen how a geothermally based heating and cooling system operates. More importantly for the present invention, the system shown is not only typical, it is employed in various ones of the on-screen displays. In this regard, attention is specifically directed to FIG. 15. In short the system illustrated in FIG. 2 provides a model for an on-screen display which is imitative of an actual geothermal system but is more particularly visually instructive in that it provides a model for which temperature, thermostat, flow rate and valve positioning are displayable in a manner which makes diagnosing systems problems particularly easy.

FIG. 3 provides a greater detailed illustration of the well shown in FIG. 2. This figure particularly illustrates a solution to an on anticipated problem in the operation of a geothermal system. In general, geothermal system designers often treat open loop systems connected to groundwater sources as being “infinite” in their thermal capacities. However, in their heating mode, geothermal systems return water to the well which is cooler than water that is extracted from the well. In the more realistic situation in which wells are finite resources, such a process can lead to situations in which the ground water source becomes too cold for efficient system operation.

In one aspect of the present invention, temperature sensor 286 is used to determine when water returned to the well is too cold for desirable levels of efficiency. Temperature sensor 286 is used to close a thermostatically controlled switch which functions to energize valve 285 so as to return chilled water to distally located dry well 290, thus bypassing return of water to open loop well 260. A useful valve of this type is the Aquastat® (a registered trademark of Honeywell International, Inc.) The dotted line connection between temperature sensor 286 and valve 285 is intended to suggest that there is the above-described functional connection between fluid temperature and the open/close status of valve 285.

Open loop well 260 has disposed at the bottom thereof pump 265. In a closed loop system pump 265 is a circulating pump. Such pumps are relatively low in power since their function is mainly to provide sufficient power to ensure flow against the normal friction that occurs when fluid flows through a conduit. However, in geothermal systems employing an open loop well, pump 265 is seen to consume more energy than a simple circulating pump since it has to raise fluid from the bottom of well 262 a surface level. Accordingly, it is noted that, in such situations, pump 265 consumes energy and its energy consumption is a factor that is to be included in determining overall system coefficient of performance. It is thus seen that in certain embodiments of the present invention there is provided a power meter which supplies information indicative of the power consumption associated with pump 265. This information is derived from a measurement of current, voltage and (optionally) phase angle associated with electrical supply to pump 265. For purposes of illustration clarity and since such connections are standard, electrical connections to pump 265 are not shown.

Revenue grade power meters/sensors are used to monitor and measure voltage, current, power and average power usage. Aggregate power usage is reported as a running total of the kilowatt-hours of energy consumed since installation of the meter. The power meters are of class one capability to account for power factor in AC inductive and capacitive circuits. Reported output in such meters reflects true power consumption. Multiple power sensors communicate these four parameters over the Modbus interface and are used to determine total electrical power consumption for all of the geothermal system components in order to calculate a coefficient of performance (COP) based on total electrical energy consumed in the transfer of thermal energy between sources and sinks

One of the significant factors in determining system performance levels is the calculation of thermal energy transport from a well. (As used herein, the term “well” refers not only to a vertical shaft but also includes angled shafts and various ones of the ground loop structures referred to above, including but not limited to, loops and coils. It is also noted that in any given geothermal system installation there may be more than one well.) In order to determine heat transfer from the well, the parameters of mass flow and temperature difference are required. Accordingly, flow meter 275 is employed to measure the rate of fluid flow. In an open loop system, the fluid is water. In a closed loop system the fluid is typically a mixture of water and antifreeze, depending upon the latitude at which the system is disposed. There is also provided pressure sensor 270. Temperature sensors (not shown) are also employed to determine the temperature of water or other fluid flowing from the ground and the temperature of water or other fluid flowing back into the ground. Here, by “ground” it is intended to denote the ground portion of the geothermal system, be it open loop or closed loop. This temperature difference along with mass flow is a determiner of the level of thermal energy extraction or thermal energy rejection into or out of the well.

Pressure sensor 270 is a device which is particularly able to provide an indication of a system fault. For example, if the power meter associated with pump 265 indicates that full power is being supplied to the pump and pressure sensor 270 indicates a lack of pressure, it is then seen that there is most likely a break in the conduit system between pump 265 and pressure sensor 270. This is only a small example of the kinds of system diagnostics that may be generated in the course of using the present invention. In closed loop systems there is a need for a continuous flow of fluid driven via a circulating pump and breaks in the conduit can introduce air which can produce deleterious cavitation effects in the pump assembly, which is yet another reason for monitoring such systems and for providing on-the-go diagnostic capabilities.

In normal operation, valves 280 and 282 are open and serve to return fluid flow back to the well. Parallel paths for fluid return to the well are provided as shown to provide redundant paths and also, in desirable circumstances, to increase the flow rate back to well 260. The present invention also permits a level of system control from a remote location. Accordingly, valves 280 and 282 may be controllable valves operable under commands from a remote location. Such operational capabilities significantly increase the opportunities for performing diagnostic tests. The fact that such tests may be performed from a remote location without requiring the presence of a skilled geothermal technician provide significant service and economic advantages. Device 281 provides an indication of power being supplied to valve 280. This valve is one that is typically open during first stage heating. Likewise device 283 provides an indication of power being supplied to valve 282. This valve is one that is typically opened during second stage heating, in addition to valve 280 being open. Devices 281 and 283 do not provide a direct indication of whether or not the respective valve is open or shut (although it could) but rather whether or not power is being supplied to a solenoid used to control the subject valve. Device 287 works in a similar fashion with respect to valve 285.

Pressure and flow meters 270 and 275 respectively are of particular note with respect to certain aspects of the present invention. In particular, such devices are easily installed in situations involving new construction. However, in situations where it is desired to deploy the present invention in an existing system, it is necessary to insert these devices in an existing conduit path. This is easily done although it may require an installation step in which air entrained in the fluid flow by the installation process is removed. It is additionally noted that since the monitoring system of the present invention is intended for use over a period of years, reliable sensing instrumentalities are very much to be desired. In particular, continued long-term functioning of pressure and flow meters 270 and 275 is very much to be desired. Accordingly, the present invention employs devices which provide indications of flow rate which in fact employ no moving parts. Such a device is Flow sensor VFS 5-100 manufactured by Grundfos, Inc.

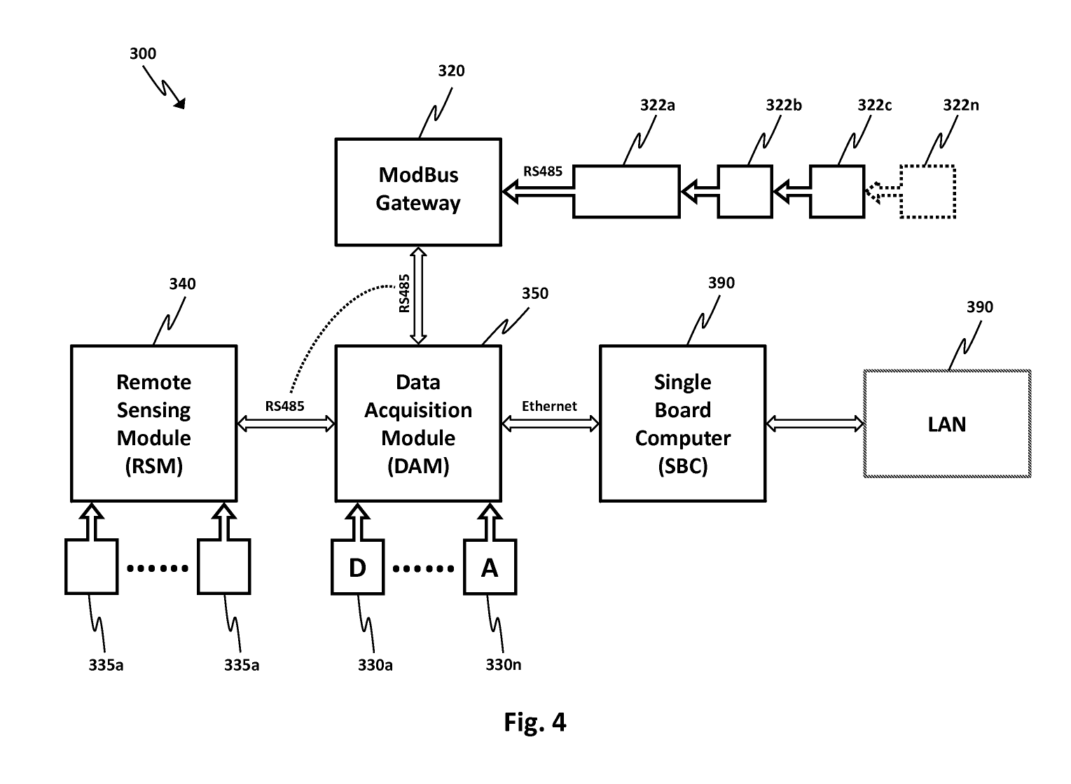

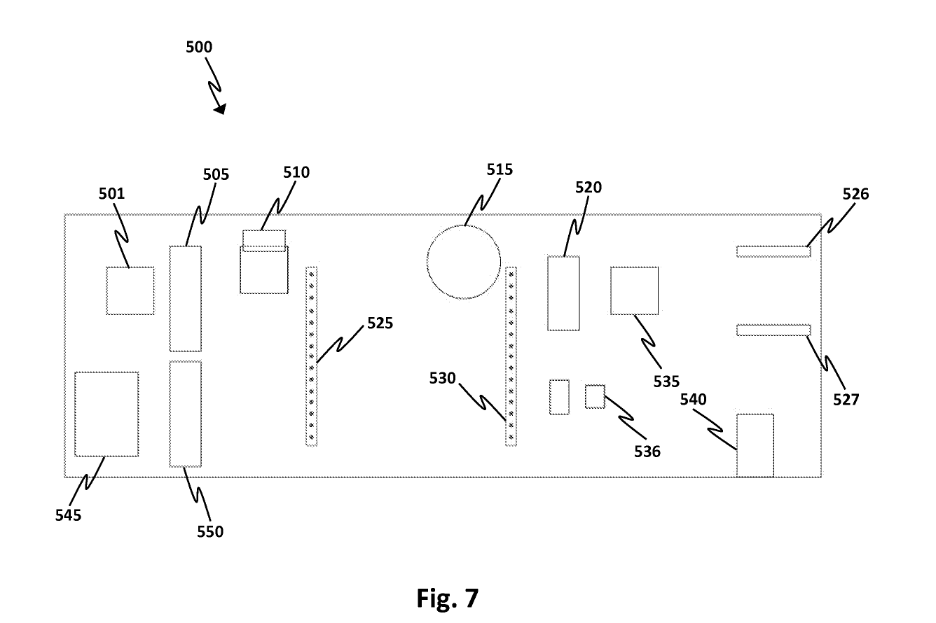

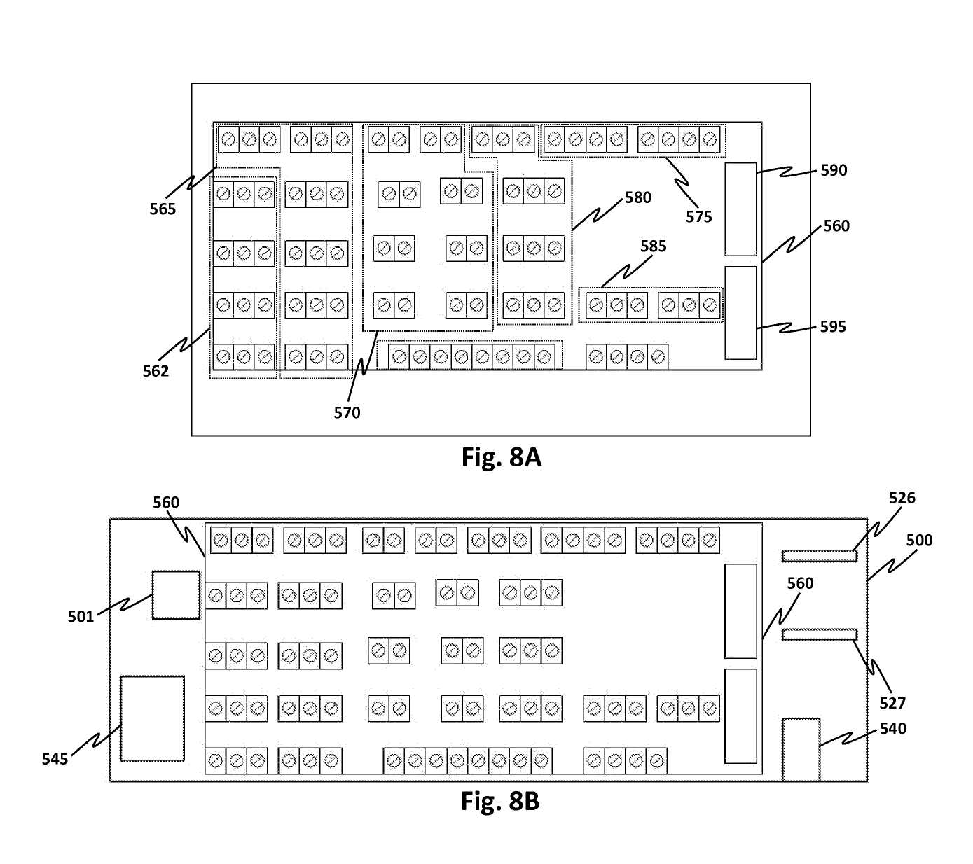

Attention is next directed to the system shown in FIG. 4. In practice, it is this system together with programming associated therewith which is intended to be a marketable package which is designed to be sold or otherwise supplied to geothermal system installers and/or geothermal system maintainers. It is the system shown in FIG. 4 that provides local intelligence, data gathering, command receiving, data formatting and data transmitting functions. In a typical installation process, an installer deploys various sensing devices and other information transducers associated with a geothermal system. These devices are connected back to connector board 560 shown in FIGS. 8A and 8B. Connector board 560 is designed to be mated with and plug into system board 500 shown in FIG. 7. Connector board (daughter board) 560 serves as the physical interface to data acquisition module mother board 500 attached to power, directly connected sensors and other boards. Additionally, the underside of connector board 560 is equipped with up to 4 or more relays to provide on/off switching capabilities for control of external devices. Additionally, the underside of connector board 560 is equipped with up to 4 or more opto-couplers to provide for sensing galvanically isolated digital inputs to provide the state of external devices.

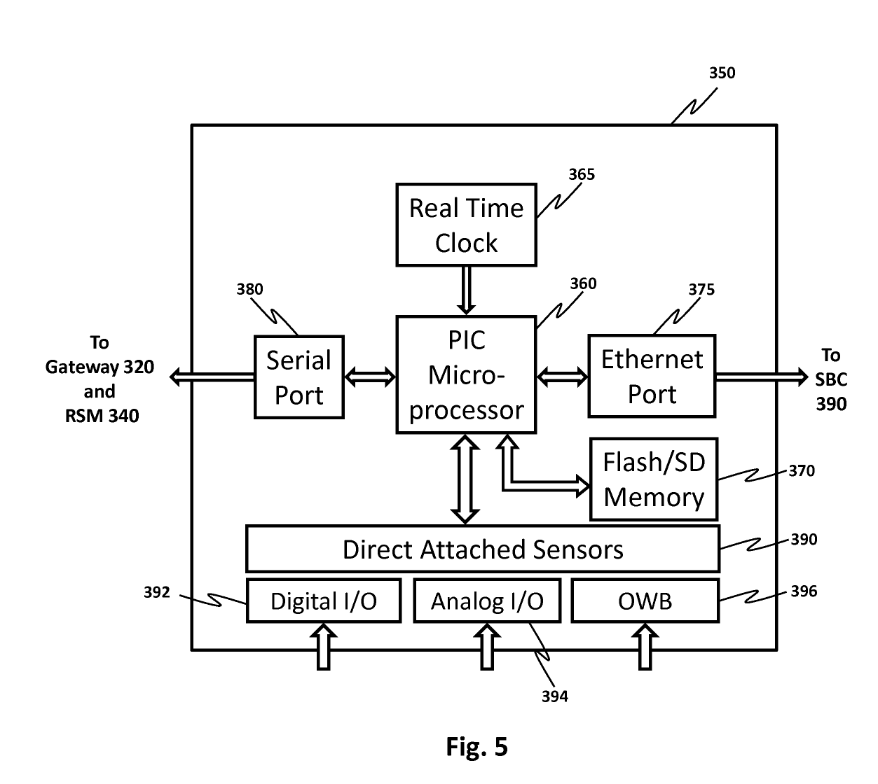

Data processing system 300 is illustrated functionally in FIG. 4. This system 300 includes single board computer 390 (SBC). SBC 390 is on the same subnet as DAM 350. Single board computer 390 connects remotely through LAN 390. Single board computer 390 performs a number of functions. These functions are more particularly illustrated in FIG. 10. Furthermore, single board computer 390, communicates with data acquisition module 350 (DAM) which is more particularly described below with reference to FIG. 5. In particular the preferable connection between single board computer 390 and data acquisition module 350 is via an Ethernet connection as shown. As is understood by those skilled in the communication arts, an Ethernet connection really means connecting to an Ethernet network. SBC 390 is a fully functional computer system employing memory, I/O and an operating system such as Unix or Linux. For the present invention, Linux is a preferable choice for an operating system due to its low cost, open structure, flexibility, ease of use and power.

Single board computer (device 390 in FIG. 4) is implemented using any conveniently available microprocessor. This includes the PIC family of processors, the ARM processor, along with the Intel-based x86 series of processors or other RISC based processors. The most relevant determiner of processor choice is cost. Likewise, cost suggests the utilization of the GNU/LINUX distribution as its operating system, as discussed above. Single Board Computer (SBC) 390 is a commodity-based computing platform providing an interface between the Data Acquisition System and the remote hosting facility. Single Board Computer 390 performs the following functions: (1) pre-processing of real time data from the Data Acquisition Module; (2) provides a centralized interface for configuring and troubleshooting the data acquisition system via the Data Acquisition Module; (3) provides an interface, for example via TCP/IP and UDP, to a central hosting facility (such as Web server 105 shown in FIG. 1); (4) forwards pre-processed data (for example, via TCP) to a central hosting facility; (5) processes alerts/alarms from the Data Acquisition Module and performs filtering, consolidating and forwarding of alerts/alarms to a central hosting facility; (6) provides transient (temporary) storage of raw data from Data Acquisition Module 350 (see FIG. 4 4); (7) provides long term storage in the event of communication (Internet) outages; and (8) provides redundant local storage.

In general, data acquisition module 350 is capable of performing the following functions: (1) interfaces via TCP/IP and UDP to the Single Board Computer via a 10/100BaseT Ethernet interface; (2) scans sensors and digital inputs attached directly to data acquisition module 350; (3) drives control relays attached directly to data acquisition module 350 and relays attached to remote sensing modules 340; (4) implements a full-duplex RS485 serial bus master interface for communication to remote sensor modules 340 and Modbus Gateway Modules 320 (MGMs) over a shared RS485 communications bus; (5) optionally interfaces to remote sensor modules 340 via a shared Zigbee wireless network; (6) implements a battery-backed real-time clock for time stamping logged data; (7) provides system synchronization for data acquisition and communications; (8) implements on-board regulated power supply circuitry for powering data acquisition module electronics, attached data acquisition module sensors and for supplying power to the remote sensor modules 340 and Modbus gateway modules 320 connected via a serial bus; (9) exchanges control and configuration information with single board computer 390; (10) exchanges control and configuration information with remote sensing module 340; (11) instructs remote sensing modules 340 to perform sensor scans; (12) logs data acquired from remote sensing modules 340 to flash storage media 370; (13) implements a file system (such as FAT) on storage media 370; (14) implements a file system on storage media 370; (15) implements a boot loader to enable remote upgrading of data acquisition module firmware; (16) implements functions to facilitate boot loading of remote sensing modules 340; (17) exchanges control and configuration information with Modbus gateway module 320; (18) instructs Modbus gateway modules 320 to synchronize sensor scans; (19) logs data acquired from Modbus gateway modules 320 to flash storage media 370; and (20) implements functions to facilitate boot loading of Modbus gateway modules 320.

In preferred embodiments of the present invention data acquisition module 350 includes at least one port that connects it to zero or more Modbus gateway module(s) 320 and to zero or more remote sensing module(s) (RSM) 340. Remote sensing module 340 is more particularly described below. Additionally, data acquisition module 350 also includes additional ports for receiving both digital (330a) and analog (330n) information from various sensors. The connection between data acquisition module 350 and Modbus gateway module 320 is preferably via a standard RS485 connection. Likewise, the connection between data acquisition module 350 and remote sensing module 340 is also preferably via a standard RS485 connection. It is, however, noted that other connection modalities may be employed without departing from the spirit and scope of the present invention.

Modbus Gateway Module 320 is intended for those connections to data transducers which tend to exhibit a greater degree of complexity (units 322a, 322b, 322c, . . . 322n, for example). Such devices typically include thermostats and power meters. In the present invention power meters are employed for the purpose of measuring energy consumption in devices such as fans and pumps and by heat pumps 200 themselves. The use and complexity of power meters is discussed above. Additionally, thermostats bring with them a level of complexity as seen in the following six thermostat parameters: (1) the configuration state a universal thermostat, including five relay states; (2) status (am I in cooling mode?); (3) mode (is heating or cooling off?); (4) upper set point temperature (for cooling); (5) lower set point temperature (for heating); and (6) currently measured/indicated temperature. In the Modbus Gateway Module 320 information structure, individual devices are addressable and the flow of information may in fact be bidirectional. In this way, one or both set points on a thermostat may be set remotely. This is in addition to a thermostats providing information to a remote location concerning current room temperature. Modbus Gateway Module 320 preferably communicates with such devices via a RS485 connection.

The serial protocol employed in the present invention in conjunction with the use of Modbus Gateway Module 320 is the RS-485 serial protocol. This protocol is used for communication between Modbus Gateway Module 320 and the relatively more intelligent devices 322a-322n and also between Modbus Gateway Module 320 and Data Acquisition Module 350.

It should be understood that Modbus is a serial exchange protocol developed in 1979 for use with programmable logic controllers. It is used in the present invention to provide a master/slave relationship between Modbus Gateway Module 320 in FIG. 4 and a plurality of daisy chained devices 322a-322n. These devices represent more complicated units found in geothermal heating and cooling systems. For example, Modbus Gateway Module 320 is employed to provide communications with a device such as a thermostat. In accordance with the present invention a thermostat is a device which has the capability of communicating a sense temperature and a temperature setting. A temperature setting is that temperature at which the space in which to the thermostat sits is its desired temperature. Since geothermal systems are almost always employed in both a heating and a cooling modality, it is seen that atypical thermostat also includes a “high” set point for use in air conditioning mode and a “low” quote set point for use in heating mode. A typical thermostat employed in the present invention also includes an indication of status and mode that is reported back to Modbus Gateway Module 320.

Another relatively intelligent device that may be found in geothermal systems, monitored in accordance with the present invention, includes a device such as a multispeed fan. In particular, such a fan is provided with a mechanism which indicates its speed of operation. This information is transmitted back to Modbus Gateway Module 320 via serial connection RS-485. This information is transmitted via a read request which is specifically “addressed” to the fan device in question. In modalities of the present invention in which remote control capabilities are provided, information concerning a desired fan speed is transmitted via the same serial Modbus connection. Similar modes of operation are possible with devices such as pumps and the geothermal heat pump system itself.

It is noted that data acquisition module 350 also preferably communicates with remote sensing module 340. Module 340 is not an essential component of all embodiments of the present invention. Remote sensing module 340 is intended to provide communications between data acquisition module 350 and various other sensing devices. The sensing devices employed with remote sensing module 340 are typically relatively simple sensor devices (flow of information in one direction only). Remote sensing module 340 is intended to provide expansion capabilities such as in those situations where a second geothermal unit is installed (as, for example, is shown in FIG. 1). In certain deployments, for example in multi-tenant building scenarios, multiple remote sensor module 340s, typically one per tenant, can connect back to a single Data Acquisition Module 350 enabling the multitenant environment to be monitored and controlled as part of a Data Processing System 300.

Modbus Gateway Module 320 is a programmable device which is capable of receiving at least some of its instructions through Data Acquisition Module 350 (FIG. 4). The Modbus Gateway Module 320 has two RS485 interfaces, one connecting to the Data Acquisition Module 350 over which the Modbus Gateway Module functions as a RS485 bus slave device, and the other interface is for communicating to sensors and devices that communicate via the Modbus protocol where the Modbus Gateway Module 320 functions as a RS485 bus master device. It is noted that the Modbus protocol is indeed a master/slave protocol. In the present invention Modbus Gateway Module 320 is assigned a Modbus address of “0” acting as the Master Modbus device. Attached sensors are slave devices. In the Modbus protocol, it is Modbus Gateway Module 320, which initiates all communications in specified format which includes an address indicating which particular Modbus addressable sensor is being targeted. This protocol is designed to provide both “read” and “write” capability.

The implementation of the present invention using the Modbus protocol and Modbus Gateway Module 320 provides significant advantages. In particular, without any changes in the hardware, it is possible to structure the present system so as to provide command and control capability to a geothermal system which is being remotely monitored. For example, it is possible in the present invention to send a command to a thermostat device telling it to change a set point temperature. In particular, the set point change commanded could be one which (knowing the presently indicated temperature) force the geothermal system into an operational mode. The system may then be remotely monitored for a response to this command. For example, remote monitoring could indicate that a fan was on, that a particular pump was operational, that a particular coefficient of performance was being achieved, or that water flow was occurring in one or more of the system's conduits. (It is noted that while the present specification refers to the fluid contained within the systems conduits as being water, the system fluid is not limited to water and, particularly in closed systems, often contains other compounds such as an anti-freeze.)

It is also to be particularly noted that, in preferred embodiments of the present invention, data acquisition module 350 and Modbus gateway module 320 share the same RS485 communications bus. By assigning different addresses to remote sensing module 340 and Modbus gateway module 320 it is possible to distinguish which unit is supplying information to data acquisition module 350. For example, one such device may be assigned an address of “1” with the other device being assigned an address of “2.”

It is noted that, as used herein, the term “sensor” is intended to include a number of different kinds of devices. These include pressure, temperature and flow rate sensors. However, the term “sensor” also refers to various forms of information transducers and devices such as a thermostat or a power meter or sensor which provide more complex data reporting functionalities. The distinction is that a thermostat typically includes upper and lower set point limits which may be controlled and other parameters as set forth above. Complex sensors have multiple parameters that are either being sensed or controlled. In such sensors, the flow of information is not necessarily unidirectional as is implied when one uses the generic term “sensor.”

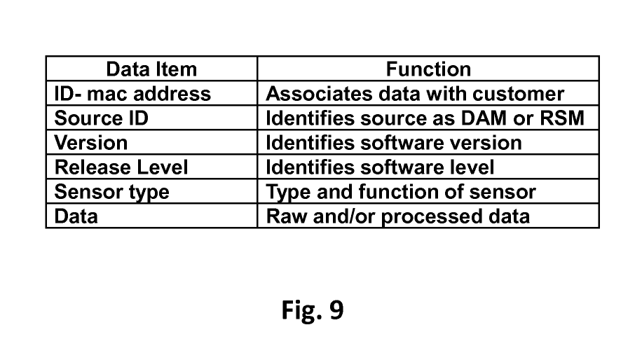

Attention is now directed to a more detailed description of data acquisition module 350 as shown in FIG. 5. One of the key facets in collecting information relating to the operations of a geothermal system is the fact that each piece of data should be attached to the time at which the subject event occurred. In particular, in the present invention a data structure is generated, referred to herein as a datagram (see FIG. 9). Each datagram entry includes an indication of a time of measurement, in short a time stamp. In order to provide such information data acquisition module 350 includes real-time clock 365 which supplies time/date information to microprocessor 360. Microprocessor 360 supports I/O processes for inter-board communications between boards, communication with sensors to collect sensor data, communicating with micro SD memory card 370, and also supports formatting UDP (User Datagram Protocol: a communication protocol in which messages are exchanged between computers in a network that uses the Internet Protocol) messages to broadcast to single board computer (SBC) 390 connected to LAN (Local Area Network) 390. In the present invention microprocessor 360 is preferably implemented as an embedded microprocessor. Microprocessing systems that may be employed include Microchip-based microcontrollers, Intel-based microprocessors or ARM microprocessors. Embedded microprocessor 360 communicates with single board computer 390 via Ethernet port 375.

Since it is undesirable that each datagram entry be supplied to the remote location as soon as it is generated, it is seen that it is desirable to store datagram information with its associated timestamp in a non-volatile memory. In the present invention, such a non-volatile memory is implemented in the form of a flash/SD card (micro SD memory card) 370 which is removable. In the event of a power failure this information is still stored and is available immediately to an on-site technician and is also available via interrogation from the remote location. This nonvolatile memory is written and read under control of microprocessor 360. While preferred embodiments of the present invention employ the use of a flash/SD card for purposes of providing a nonvolatile memory, other nonvolatile memory formats may also be employed.

DAMs incorporate a microSD card interface used as a primary data logging interface for the system. Data is logged at various intervals whose lengths are remotely configurable. SD media 510 in FIG. 7 is also used to store bootloader images for DAM 350, RSM 340 and MGM 320 modules. DAMs have a configurable system sampling rate currently implemented at 1 Hz. Data from the directly attached sensors and digital inputs together with the data from all RSMs and MGMs is aggregated, along with status information and forwarded to SBC 390 in real time for subsequent downstream processing. The real time analog sensor data is averaged over an installation configurable period and logged to the SD media. Typical values for the averaging period include 1 minute, 5 minute, 10 minute, 15 minute, 30 minute and 60 minutes. Random Access Memory (RAM) is a typically a limited resources on embedded controllers. In the present invention, in order to minimize the amount of memory required for averaging sensor data, the averaging function for sensors connected to Remote Sensor Module (340) are performed by the Remote Sensor Module 340 in response to a command from the Data Acquisition Module 350 and then transmitted to the Data Acquisition Module 350 for logging. Similarly the averaging of data for sensors connected to the Modbus Gateway Module (320) are performed by the Modbus Gateway Module 320 in response to a command from the Data Acquisition Module 350 and then transmitted to the Data Acquisition Module 350 for logging. Logged data is stored in a data subdirectory. A new subdirectory is created at midnight each day. The directory name is fixed length name of the format YYMMDD where: YY=Year 2000 to 2099; MM=01 to 12; and DD=Date 01 to 31. Data filenames are of the form YYhhmmss.DOY where: YY=Year 2000 to 2099; hh=Hour 0 to 23; mm=Minute 0 to 59; SS=Second 0 to 59; and DOY=Julian Day of the year. Importantly, for practical aspects of the present invention, when the remote communication link (typically the Internet) is down, a database having these named files and subdirectory structure begins to fill up. Information is then transferred from the SD card on DAM 350 to SBC 400 via its MAC address and it is stored therein using date and time information. Records are appended to a file about every five minutes. At the end of this transfer, the file is closed and moved to another subdirectory. Both parsed and unparsed data is stored in SBC 400 for later transfer to host 105. Once it is determined that communications are restored and it is determined that a significant amount of data is stored, files are transferred to host 105 according to several possible criteria: (1) Last-in-first-out (LIFO); (2) use of coarser time divisions (hours vs. minutes); and (3) criticality. Other methods for determining which files to send may also be employed, it being understood that the essential reason for resorting to immediately sending fewer than all the files is due to the fact that a long duration outage results in the accumulation of significant amounts of data.

It is also seen from FIG. 5 that microprocessor 360 communicates over serial port 380 to both Modbus gateway module 320 and remote sensing module 340, in the addressable fashion described above. Data acquisition module 350 is thus seen to interface with remote sensing module 340 via a shared RS485 half-duplex serial bus. Optionally, though not illustrated, this interface may also be provided via a Zigbee or other wireless protocol. In short, the present invention is not limited to direct connections between various ones of its components. Wireless interconnections may also be employed. Lastly, it is seen that port 390 is provided for communications with relatively simple sensing devices such as pressure, temperature and flow rate indicators. These devices may be digital (392), analog (394) or may occur over a so-called one-wire-bus (OWB, 396).

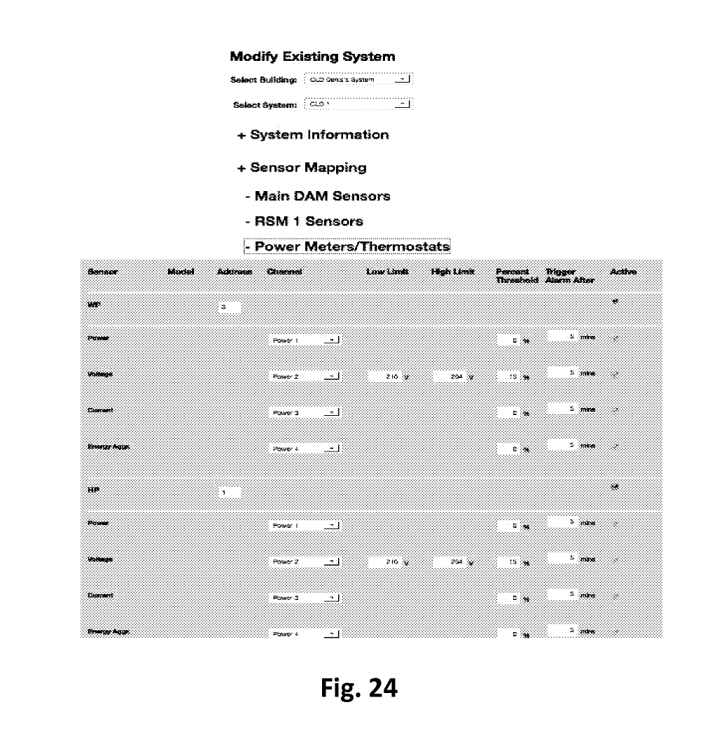

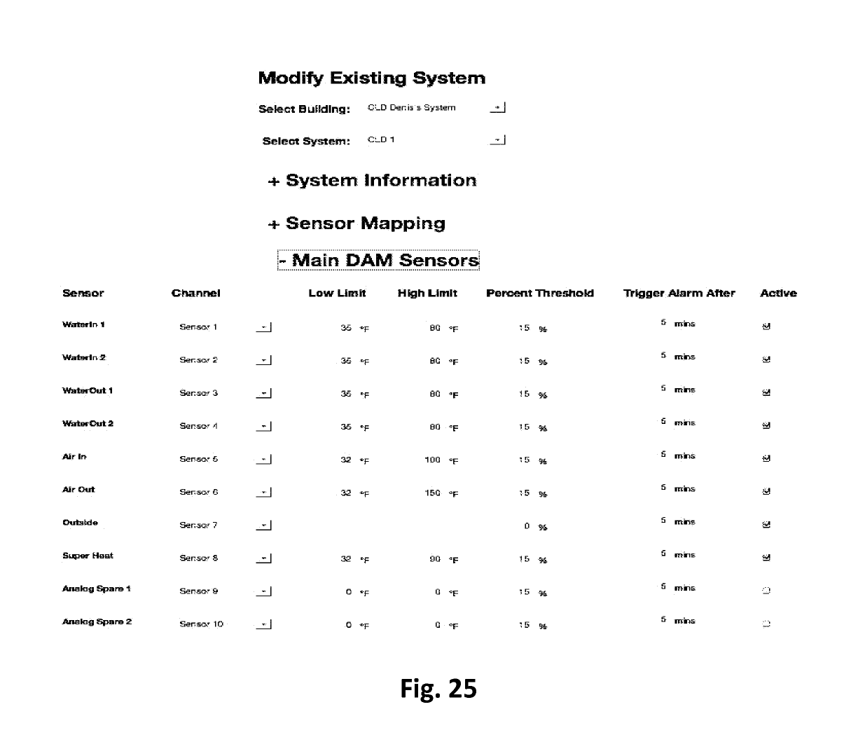

At this point in the discussion it is useful to consider the structure and function of remote sensing modules 340. Remote sensing modules (RSMs) 340 are similar to data acquisition modules (DAMs) 350. However, remote sensing modules 340 do not contain a real-time clock or a battery. RSMs include a microprocessor (typically a Microchip PIC embedded micro controller) for logic and also include RAM and EEPROM for storage. RSMs also do not have an Ethernet adapter for attaching to a LAN. Their communications to other boards is via RS485, as shown. In a typical deployment scenario, RSMs do not require relays for control purposes. In the present implementation of the invention the Remote Sensing Modules 340 share the same Connector Board 560 as the Data Acquisition Module 500 but without the relays being populated on the Connector Board 560. This RSM implementation does not preclude populating the relays on the Connector Board 560 for use on the RSM and, as a consequence, the RSM can be configured to control these relays. An RSM will typically carry out the following functions: (1) implement a half-duplex RS485 serial bus slave interface for communication to data acquisition module 350; (2) optionally interface to the data acquisition module 350 via a wireless interface; (3) implement on-board regulated power supply circuitry for powering the remote sensing module electronics and attached sensors that are powered either via an external power supply connector or via power pins on the RS485 serial bus connector; (4) exchange control and configuration information with the data acquisition module sample sensors connected directly to the RSM; (5) transfer sensor data to data acquisition module 350 under control of the data acquisition module; and (6) implement a boot loader to enable the remote upgrade of RSM firmware. Monitoring system configuration occurs at the Remote Monitoring site when the system is configured via the configuration screens such as shown in FIG. 24. Configuration and/or reconfiguration occurs locally on the SBC where changes to the system configuration are made. Configuration and/or reconfiguration also occurs within the DAM. Such changes are made via access from the SBC directly or via a bootloader.

Preferred embodiments of the present invention collect data associated with certain sensory inputs, including digital information reflecting an energized state of attached geothermal system components. A number of these inputs are temperatures. These temperatures include, but are not limited to, the following: (1) entering water temperature from the ground loop (or the well); (2) exiting water temperatures into the ground loop (or the well); (3) supply temperature of fluids in the air/water heat transfer system (heat exchanger 230); (4) return temperature of fluids in the air/water heat transfer system; (5) outside air temperature (OAT); (6) ambient room temperature; and (7) other air temperatures as needed or desired.

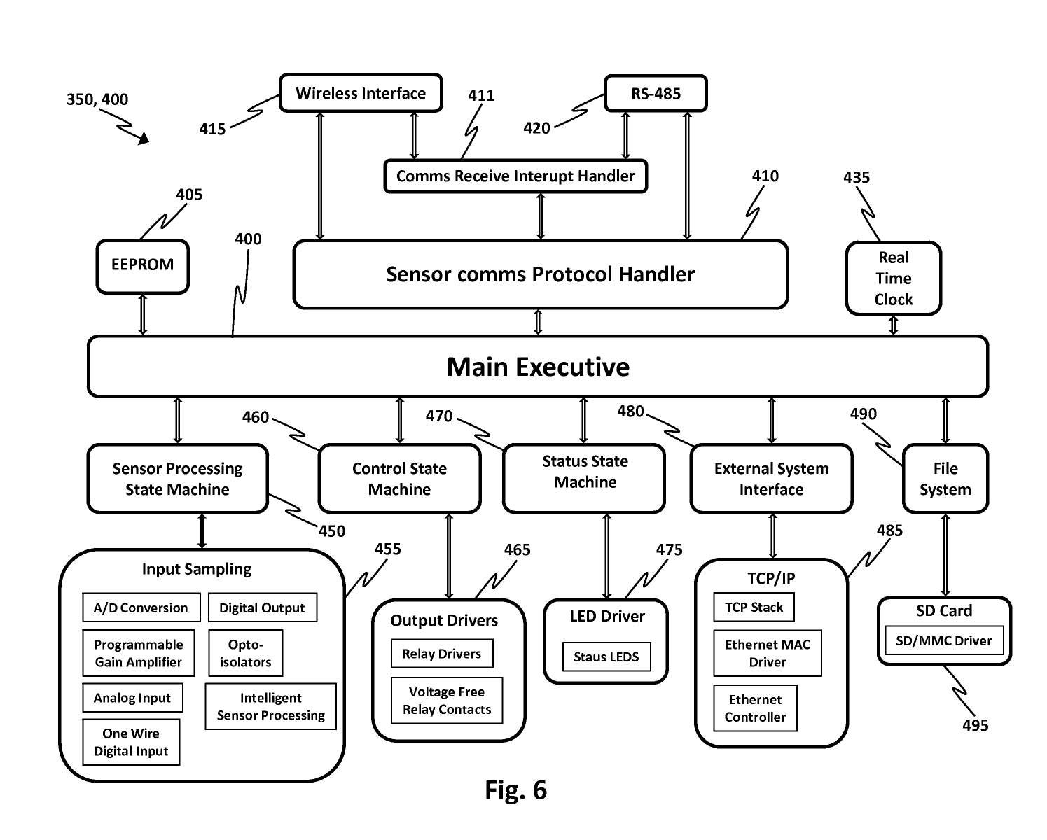

Attention is now directed to FIG. 6 which illustrates a useful structure for software present in data acquisition module 350. In particular, it is seen that main executive 400 interfaces with a plurality of subsystems including real-time clock 435 (see also 365 in a FIG. 5). For example to provide an Ethernet connection, external system interface 480 provides a connection through the standard Internet TCP/IP protocol 485 which supports a TCP stack, and Internet MAC driver and an Ethernet controller.

The DAM incorporates a 10/100 BaseT Ethernet interface. This interface is the external system interface used to communication with Single Board Computer System (SBC) 390. This interface is used for static and dynamic data, control and status information between the SBC and the DAM. DAM 400 includes data and control interfaces to SBC 390. Real time data is sent from DAM 400 to SBC 390 every scan interval. Users interact with DAM 400 via SBC 390. User commands, which are restricted to a limited number of service employees, support the following instructions: (1) list the directory of the SD Media; (2) delete files on the SD media; (3) transfer files to and from the SD media; (4) reset DAM 400; (5) reset a RSM assuming the RSM_ID or MGM_ID is known; and (6) initiate a RSM bootload.

Main executive 400 also interfaces to file system 490 which is connected to a local SD card 495 (370 in FIG. 5). In the present invention the preferably implemented file system is the so-called FAT system, as is often used in personal computers. Main executive at 400 also has access to local storage in the form of EEPROM 405. EEPROM 405 maintains deployment specific information that may include system wide configuration information as well as sensor specific linearization coefficients and sensor maps for mapping specific sensors to associated sensor inputs. The EEPROM also stores bootloader parameter information.

DAM software has two main code assemblies, a bootloader and DAM Data Acquisition Application software. The bootloader enables new versions of the DAM Data Acquisition Application to be uploaded to the DAM. The bootloader is entered automatically on power on of the DAM and remains in bootloader mode for a period of 5 seconds, unless captured, before passing control the DAM to data acquisition application software. When an RSM bootload is initiated, data acquisition and logging is suspended. The RSM bootload support logic is part of the DAM Executive, it is not part of the DAM bootloader logic. This system makes remote updating of software and system parameters possible.

In preferred embodiments of the present invention the data acquisition modules are provided with indicator lights preferably implemented as LED devices. Accordingly, there is provided a status state machine 470 which is essentially a software implemented state machine used to provide an indication of various DAM states. Status state machine 470 thus controls LED driver 475 to provide a desired external status indicator. Status State Machine 470 controls the illumination of a series of status LEDs that are used for information and debugging purposes. DAM 400 incorporates the following LEDs: (1) Status —Green LED flashes twice per second in normal operation; (2) Comms—Flashes when processing a message from an RSM; (3) Fault—Red LED illuminated on fault; flashes at 10 times per second in bootloader mode; (4) Service—Blue LED for on-site maintenance support.

In those circumstances where the system of the present invention is intended to provide a control function at the remote site, there is provided Control State Machine 460 which controls output drivers 465 to provide control of various relays and voltage free relay contacts. Control State Machine 460 is responsible for system wide setting and clearing of control outputs across distributed system. The system control outputs are typically voltage free contacts located on DAM 350 and optional relay modules connected to RSMs. There are up to four relays currently disposed on DAM 350.

The primary function of data acquisition module 350 is implemented via main executive 400 and its control of Sensor Processing State Machine 450. This state machine controls input sampling from a plurality of sources 455, as shown in FIG. 6. Sensor Processing State Machine 450 is responsible for the generation of system wide sensor scan synchronization via the generation of a RSM_Scansynchronization message distributed by the Sensor Comms Protocol Handler 410. This enables the acquisition sensor data from all sensors in the distributed system to be synchronized resulting in minimal jitter between sensor sampling across the distributed system. The Sensor Processing State Machine scans, synchronizes directly attached sensors, remote sensor modules and digital inputs approximately every 5 seconds. (This is a convenient timing choice, not a mandated one.) This enables the acquisition sensor data from all sensors and digital inputs in the distributed system to be synchronized resulting in minimal jitter between sensor sampling across the distributed system. DAM module 350, 400 supports the following sensor inputs connected to the DAM: (1) one-wire sensor bus supporting multiple sensors; (2) one-wire sensor test bus; (3) 4 unity gain analog inputs supporting single ended 0.6 to 3.6 volt sensor inputs; (4) 5 general purpose analog inputs with variable offset and gain supporting differential and single ended sensors; differential sensors each employee two analog inputs; (6) 8 opto-isolated digital inputs.

External communications from data acquisition module 400 are processed through Sensor Comms Protocol Handler 410. Sensor Comms Protocol Hander 410 is responsible for encoding packets from DAM (400, 350) to RSM 340 for the RS-485 (420) and wireless interface (415). Similarly DAM (400, 350) decodes packets from RSM 340 via the RS-485 (420) and wireless interface (415). Comms Receive Interrupt Handler 411 queues packets received from the RS-485 (420) and wireless interface 415 and queues them in media specific receive buffers for subsequent processing by Comms Protocol Handler 410.

DAM (400, 350) is powered by a nominal +12 volt power source. The on-board power supply of DAM (400, 350) provides a filtered +12 volts DC feed for the RSMs via the RS-485 sensor bus. DAM 400 incorporates reverse-polarity input diode protection on the power supply inputs.

The following table lists system wide messages that are exchanged between DAM 400 and RSM 340, and between the DAM 400 and the MGM 320:

TABLE I

| Message | Source | Type | Action |
|---|---|---|---|
| DAM_Bootload | RSM/MGM | Unicast | Bootload command |
| | | | confirmation |
| DAM_Config | RSM/MGM | Unicast | Response to |
| | | | RSM_GetConfig |
| DAM_Data | RSM/MGM | Unicast | Response to |
| | | | RSM_GetData |
| DAM_LEDStatus | RSM/MGM | Unicast | Response to |
| | | | RSM_GetLEDStatus |
| DAM_ModbusCommand | MGM | Unicast | Response to |
| Response | | | MGM_ModbusCommand |
| DAM_ModbusConfig | MGM | Unicast | Response to |
| | | | MGM_ModbusConfig |
| DAM_Output | RSM/MGM | Unicast | Response to |
| | | | RSM_GetOutput and |
| | | | RSM_SetOutput |
| DAM_Ping_Response | RSM/MGM | Unicast | Response to |
| | | | RSM_Ping command |
| DAM_Status | RSM/MGM | Unicast | Response to |
| | | | RSM_GetStatus |
| MGM_ModbusCommand | DAM | Unicast | Modbus command to be |
| | | | transparently passed by the |
| | | | addressed MGM to the |
| | | | MGM's Modbus interface |
| MGM_ModbusConfig | DAM | Unicast | Configure/Query the MGM |
| | | | Modbus database for the |
| | | | addressed MGM |
| RSM_Bootload | RSM/MGM | Unicast | Put the target RSM/MGM in |
| | | | bootloader mode |
| RSM_Config | DAM | Unicast | Configure the target RSM |
| RSM_GetOutput | DAM | Unicast | Reads the RSM digital |
| | | | output states |
| RSM_SetOutput | DAM | Unicast | Sets RSM digital outputs as |
| | | | per the message payload |
| RSM_SetMonitorLED | DAM | Unicast | Sets the RSM/MGM Monitor |
| | | | LED |
| RSM_FlashMonitorLED | DAM | Unicast | Flashed the RSM/MGM |
| | | | Monitor LED |
| RSM_ClearMonitorLED | DAM | Unicast | Clears the RSM/MGM |
| | | | Monitor LED |
| RSM_GetLED Status | DAM | Unicast | Returns the current status |
| | | | of all RSM/MGM LEDs |
| RSM_GetConfig | DAM | Unicast | Returns RSM/MGM Sensor |
| | | | Configuration |
| RSM_GetData | DAM | Unicast | Returns RSM/MGM most |
| | | | recent Data sample |
| RSM_GetAvData | DAM | Unicast | Returns RSM Averaged Data |
| RSM_GetStatus | DAM | Unicast | Returns RSM/MGM System |
| | | | Status |
| RSM_Ping | DAM | Unicast | Test reachability of targeted |
| | | | RSM/MGM |
| RSM_Reset | DAM | Unicast | Resets the target RSM/MGM |
| RSM_Synchronization | DAM | Broadcast | Instructs RSM to scan |
| | | (implied) | sensors |
| | | | Data transfer from the |
| | | | RSM/MGM to DAM is |
| | | | synchronized to the message |
| | | | A time stamp constructed |
| | | | from the Date and Time |
| | | | information from the DAM |
| | | | RTC is passed via this |
| | | | command to the RSM/MGM. |
| | | | This time stamp is used |
| | | | to time stamp data records |
| | | | from the RSM/MGM |

FIG. 7 is a schematic view of a top view of a printed circuit board 500 implementing data access monitor 400 in accordance with one embodiment of the present invention. In particular, Ethernet adapter 501 is seen on the left side of circuit board 500. Below Ethernet adapter 501 is seen RJ-45 connector 545. To the right of these elements there is seen expansion bus adapters 505 and 550. To the right of these elements there is seen SD card 510 and the receiver into which it is inserted. To the right of these elements there is seen connector board sockets 525 and 530. It is these sockets which are used for mating connector board 560. Additionally shown in FIG. 7 there is the battery 515 which the powers real-time clock 520. Further to the right there is seen EEPROM memory 536. Above EEPROM memory 536 there is also seen microprocessor 535. In current implementations of the present invention, this microprocessor is a Microchip PIC microcontroller. In the lower right-hand corner of printed circuit board 500 there is also seen connector 540 through which a 12 V DC power supply is connected. Lastly, connectors 526 and 527 are connectors that are connectable to a wireless module since wireless connections are one of the options employed in one of the more general embodiments of the present invention.

FIG. 8A is a top view similar to FIG. 7 except that it illustrates the arrangement of connectors on connector board 560. This board contains a number of different connectors, as shown. It plays a significant role in the present invention in that it is easily separated from printed circuit board 500 which may be replaced or updated or serviced. Connector board 560 is essentially the hardwired interface between data acquisition module 400 and the various sensors and/or other information transducers associated with the geothermal heating/cooling system which is being monitored and/or controlled. Accordingly, it is seen that the physical connection to any hardwiring present in and installed system is made through connector board 560.

FIG. 8A shows a number of connectors. For purposes of organizational simplicity, these connectors are arranged in a plurality of different areas on connector board 560. These regions are outlined using dashed lined outlines in the drawing. However, it should be understood that the dashed lines are provided solely for the purpose of illustration. Furthermore, is noted that while FIG. 8A illustrates a certain organization of collectors, this organization is for convenience and is not a limiting factor in the design or construction of the present invention. In particular, region 562 denotes an area of connectors set forth for connection to flow and pressure sensors. Region 565 denotes a set of connectors allocated for analogue inputs. Region 570 on connector board 560 provides connections to digital I/O devices. Region 580 provides connections to various relays that may be employed, particularly in the event that system control functions are implemented in the present invention. Region 575 is allocated for RS-485 connections. Region 585 is allocated to one-wire bus connections. Connectors 590 and 595 provide expansion capabilities.

FIG. 8B illustrates the situation in which connector board 560 is plugged into printed circuit board 500. It is noted that the boards 500 and 560 in FIG. 7 and FIG. 8A are not drawn to the exact same scale. Circuit component's shown on printed circuit board 500 are provided with a set of reference numerals consistent with those shown in FIG. 7. For convenience, reference numerals are not shown for connector board 560 in this view. There are nonetheless clearly evident in the view shown in FIG. 8A.

FIG. 9 is an illustration of the datagram structure employed in the communication of information packets in the operation of the present invention. In particular, each system contains an ID-mac address which is a globally unique identifier used to associate the data packets with a given Data Acquisition Module/customer (that is, with a given remote installation). There is additionally provided a Source ID which Identifies the data source as DAM or RSM or as Modbus Gateway Module 320 (as discussed above). Software version and release information are also provided. There is also a field in the datagram which characterizes the type and function of a subject sensor. Lastly, raw and/or processed data is included in the datagram.

FIG. 10 provides a description of the end-to-end data flow in the present invention starting from the receipt of information in data acquisition module 400 and terminating at Web server 105. In particular, it is seen that FIG. 10 illustrates four layers of processing. A first layer occurs via processing by data acquisition module 400. Next, local single board computer 390 carries out data normalization, packaging, formatting and transmission protocols. Next, a host database and back end server receives and processes files and uploads them to a data warehouse from which a host web and application server is employed to provide access to collected database materials.

One of the significant advantages of the present invention is that for each remote system being monitored and/or controlled, a database is generated which provides a history of remote system operation. This facilitates a detailed analysis of various remote system parameters to be carried out off-line at a later point in time, whether or not this analysis is carried out in response to a system generated alert. This database also provides a mechanism for an intelligent knowledge based processor to parse information found in the database and to provide real-time alerts and analyses of system operation. Additionally, the user interface web portal allows the generation of an access to performance data for later off-line uses. In particular, it is seen that the construction of the database of datagram information herein provides significant advantages and a structure in which the subject information may be accessed and analyzed.

A detailed description of the information flow seen in FIG. 10 is now provided. In particular, in step 610, data acquisition module 400 polls various ones of the sensors and additionally polls remote sensor modules 340 and Modbus Gateway Module 320 (step 615). Next data acquisition module 400 formats and broadcasts the datagram material to single board computer 390 (step 620).

Single board computer 390 “listens” for this information on the UDP socket (step 630) and subsequently accepts the receipt of these packages (step 635). In step 635, a socket program is invoked to receive a multicast UDP datagram. Each payload datagram packet is based upon the source ID. See FIG. 9. In the present implementation, a unique source ID is reserved for Modbus Gateway Module 320. Notably, particular installations of the present invention employ multiple Modbus Gateway Modules, each having a unique ID. Next single board computer 390 parses and converts the raw data, configures an output format, loads the local database, and builds and stores a formatted file.

Single board computer 390 then parses, converts and normalizes raw data (step 640). After that, it configures the output (step 642) and loads the local database (of datagrams; step 644). Lastly, single board computer 390 builds and stores a formatted database (step 646). This database comprises a number of distinct files. The files are established with a hierarchical naming convention such as that described above and also include time stamp and MAC address information for slotting into folders

In steps 640 to 646, single board computer 390 parses the data, converts and conforms it to a usable representation, maps input positional data based on customer configuration files, follows collation rules to group and slot data for appropriate system processing, loads the data to a local database for archiving and uploads the data based upon the actions of a “cron” routine. Single board computer 390, using a “cron” routine, a daemon and the Secure Shell protocol (SSH), uploads an encrypted file to host 105 every five minutes (650). “Cron” is a time-based job scheduler in Unix-like computer operating systems. It is used to set up and maintain software to schedule jobs (commands or shell scripts) to run periodically at fixed times, dates, or intervals.

The database information is thus delivered to a host database server and to a host web application server. These servers typically reside in the same physical structure and location at a single installation; however, they may in fact be disposed at different locations. Host database server receives and processes the transmitted files and upload them to a data warehouse for instantaneous access or for access at a later time. As stated above this access may be for purposes of alert, alarm, diagnoses or simple reporting (660). In step 660, database file information is processed based on a client's configuration file in which processing it validates the file, reformats the file as necessary, uploads the file, creates a transaction log database for record-keeping purposes and invokes exception handling routines as needed.

As seen in FIG. 10 host database and back-end server also includes programming that implements some form of query capability. As shown, SQL 670 possesses known functionality, which implements queries against a database.

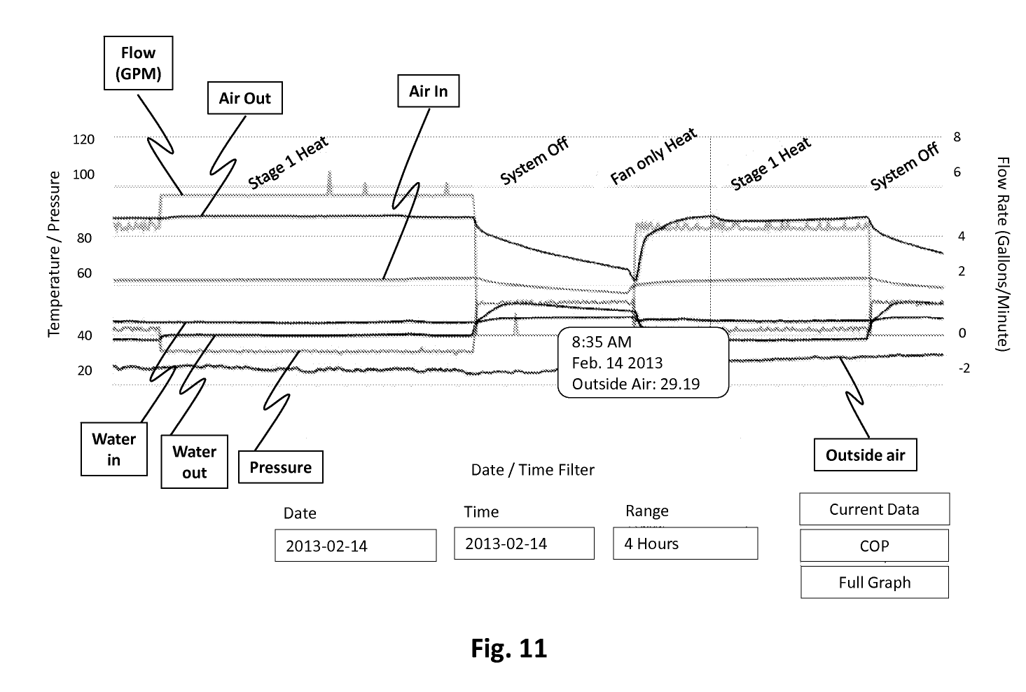

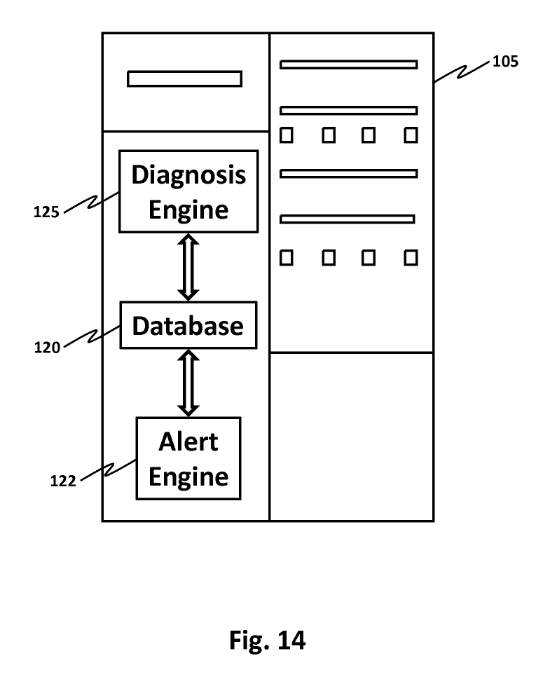

Lastly, web server 105 shown in FIGS. 1 and 14 comprises a database configured as a central repository for storing data collected from all sites, not just the single site illustrated in this figure. The information is available for end use based on privileged access and authentication rules. A web interface is used by the end user to view the information, run ad hoc queries and generate reports for viewing on line or for downloading to a local workstation. Custom queries and additional alerting through email and text messaging provide a capability to support the various diagnostic, maintenance and service issues. At this level, display of data is also carried out. In particular, it is noted that FIGS. 11-13 and FIGS. 15 through 24 illustrate particular examples of information that is displayed. See step 675 in FIG. 10. These figures illustrate system “dashboards,” tables, graphs and other system and programming status information. A typical “dashboard” is illustrated in FIG. 15.

A typical use case for the web server portal for a service provider is a view of all or a subset of client systems which reports status for prescribed monitoring interval. It could be a color-coding scheme indicating system health for a quick status check. Red, yellow, green and black are used to indicate status or level of severity of a problem for further investigation.

Other views capable of being generated from the generated and transmitted data provide greater detail with a “drill down” capability for identifying component failure. In addition to viewing current status, the historical data allows looking back at a time-stamped snapshot, at a point in time leading up to an event, to see when a failure first occurred and any related component behavior. Graphs depicting the portion of run-time spent in different stages of heating and cooling, are generated against real data from the database. This data is used to verify system design against real load conditions.

FIG. 11 illustrates a sample display screen generated from database logging information created by the present invention. In particular, it is seen that the data displayed illustrates the status of various system parameters over a four hour period. The display shown is an actual representation of data collected on a particular day within a particular time window. The horizontal axis represents time. The display in reality is provided in various colors. Unfortunately, these colors are not available in the included patent drawing. The display includes a color key as shown below the graph. Since this color code is not visible in the drawing, it is replaced by the following listing of the parameters shown as annotations: air out; air in; flow; water in; pressure; water out; and outside air.

The illustration shows several different overall system states. On the left there is shown the system status during stage one heating. When the stage one heating terminates, the system is off. Next the system goes into a state in which only the fan is operative. It then goes into a second period of stage one heating followed by a period of time when the system is off.

It is clear that this data is useful for performing heating system diagnoses. It is also useful for calculating the coefficient of performance, which can be monitored over a period of time in order to detect degradation of system performance. For example, consider the situation in which the system calls for heat and there is already an indication that stage 1 heating is turned on. There should be a measurable temperature differential between “water in” and “water out” indicating heat transfer is taking place. If no temperature difference is indicated, then it is clear that there are problems with the system. Likewise, problems are illustrated by the observation that there is little or no difference between “air in” and “air out.” Lack of flow is also indicative of a system problem as is abnormal variations in flow or pressure. In this regard, it is to be particularly noted that all of the data illustrated in FIG. 11 is displayed and gathered at a remote location. This data may be collected and observed on a real-time basis or may be utilized in an after-the-fact mode. Additionally, it is noted that this data is cumulative over time and stored in the database facilities of the present invention and may be used to monitor system performance and efficiency over relatively long periods of time. This mode of operation is particularly useful for detecting degradation in system performance under various conditions.

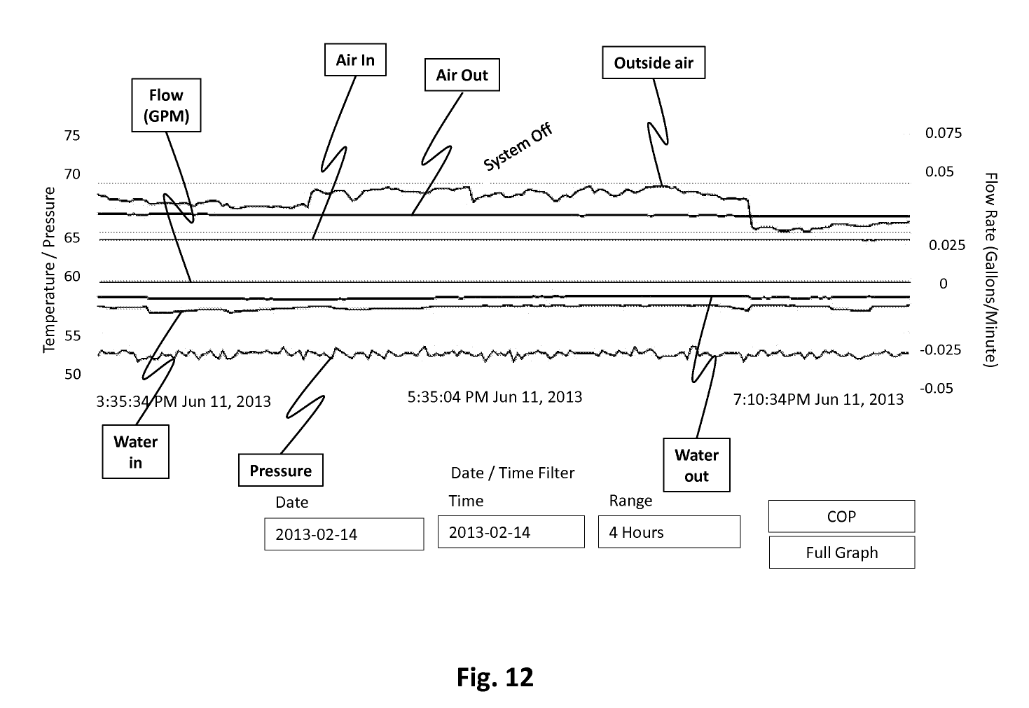

FIG. 12 is a view similar to that shown in FIG. 11. A significant difference, however, is that it depicts a different time of day. Another difference is that it illustrates a measured value of system parameters over a sustained period of time when the heating/cooling system is off. In both FIGS. 11 and 12 system operation is illustrated with 7 desirable parameters. Note also the presence of screen icons labeled “current data,” “COP” and “full graph” seen in FIGS. 11 and 12. These icons can be clicked upon by a user at a remote site (or even on-site) to display additional data and greater detail. In particular values of current data may be displayed along with a value indicating the coefficient of performance. A “full graph” mode is also selectable so as to display the most complete set of varying analog data. Digital information such as “fan on” or “fan off” is also displayable, as seen in FIG. 15, discussed below.

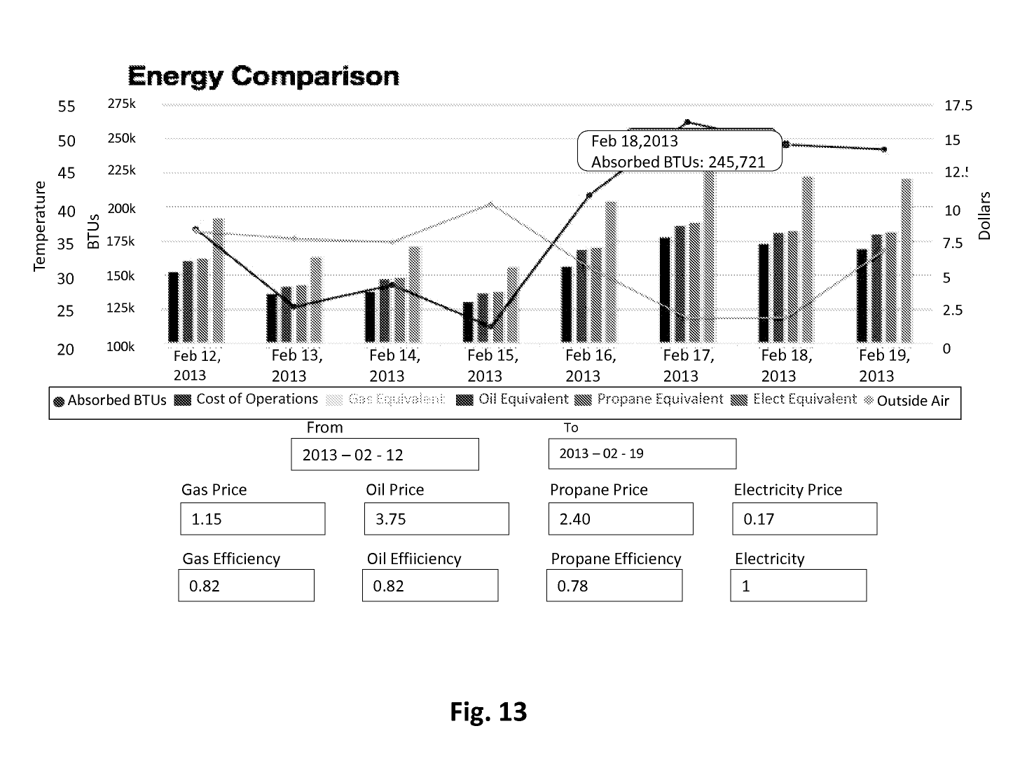

FIG. 13 provides graphical information concerning the cost of system operation and provides an indication of energy savings, particularly as measured in dollar costs. In particular, looking at the four bars for the date of Feb. 12, 2013, it is seen that there are four values illustrated. From left to right, these values are: cost of operation; the oil equivalent cost; the propane equivalent cost; and the electrical energy equivalent cost. Similar bar graphs are presented for a total of eight days as shown. Also illustrated is a line graph depicting outside air temperature and the level of heat energy claimed from the ground source in BTU's. At the bottom of the illustration in FIG. 13 there are shown cost values for various ones of other potential heat energy sources (oil, propane, electrical). These values may be changed by a user of the present invention to generate a different set of comparative bar graphs. Furthermore, it is to be observed that the lower the outside air temperature, the greater the number of absorbed BTUs. In particular, it should be observed that the graphs shown in FIG. 13 provide the homeowner and service personnel with indicia of the value of ground source heating and cooling systems.

FIG. 14 illustrates the use of Web server 105 to perform diagnostic and alerting functions. At the core of the present invention it is seen that there is created a database characterizing time-based system parameters for remote geothermal heating/cooling systems. Database 120 is structured in several layers. At an upper layer it is divided according to customer. That is to say, each remote location is represented in a section of database 120. At a layer just below “customer,” there is a layer indexed by time. Using database 105, focused upon a given customer, diagnostic engine 125 is deployed on the host to analyze not only current heating/cooling system status but also past system status and events. In particular, diagnosis engine 125 is invokable on demand by service personnel (or even an end-user) to access customer data to determine the existence and nature of potential system problems. In addition, alert engine 122 operates on a continuing basis to observe remote system data and to generate an alarm should system parameters not conform to normal system operation and in particular whether or not the system operation in question is based on a heating function or a cooling function.

FIG. 15 illustrates a “screen shot” which particularly emphasizes a significantly useful feature of the present invention namely that measured system parameters and their values are illustrated on a diagram similar to that shown in FIG. 2. In particular, the system of the present invention provides an illustration of a standard ground source heating and cooling system. More particularly, the present invention provides an on-screen illustration of various parameters associated with various aspects of the physical cooling system. In particular, the present invention provides a capability for mapping measured remote data onto a display, which provides a particularly useful human interface to the system being monitored. It is as if the system being monitored were present on the computer screen of the present invention replete with a full set of measured data values indicating temperature level, flow rates, pressures, electrical power, and system status. Arrows above and to the right are screen icons that permit the user/viewer to step forward or backward in time. This is a particularly useful view in terms of providing an enhanced diagnostic function.

Since the present invention also provides a remote capability for certain aspects of system control, information displayed on a computer screen such as seen in FIG. 15 is particularly useful. This functionality is particularly useful for correlating demand to system response. For example, if the set point for temperature on a thermostat coupled in to the present invention is raised, it is very useful to be able to monitor the fact that, as a result of this action, certain valves are open, certain pressure levels change, fan operation is varied and measured temperature increases as well.

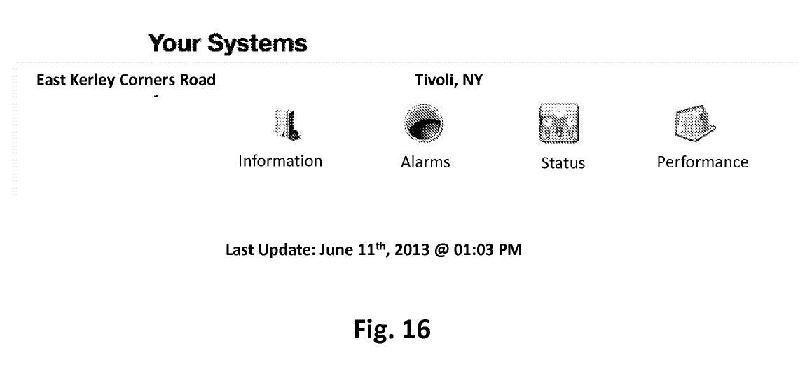

FIG. 16 illustrates a screen shot showing a page of computer software interfacing in the present invention that is presented following selection of a particular customer. In particular, the customer's location is described in terms of a particular physical address. An icon is also displayed and illuminated should there be any alarms associated with this particular customer. Another on-screen icon allows the user of the present invention (here typically service personnel) to access status information associated with the customers system. Typical status information is similar to that shown in FIGS. 11 and 12 discussed above. Additionally, another icon labeled “performance” is provided in order to allow service personnel and/or customers to access performance data associated with the geothermal system in question. Lastly, and icon labeled “information” is provided to allow the user to access information particular to the site in question such as the brand name of the system installed, its year of installation and perhaps information as to whether or not this particular user is current in his/her payment for system monitoring services.

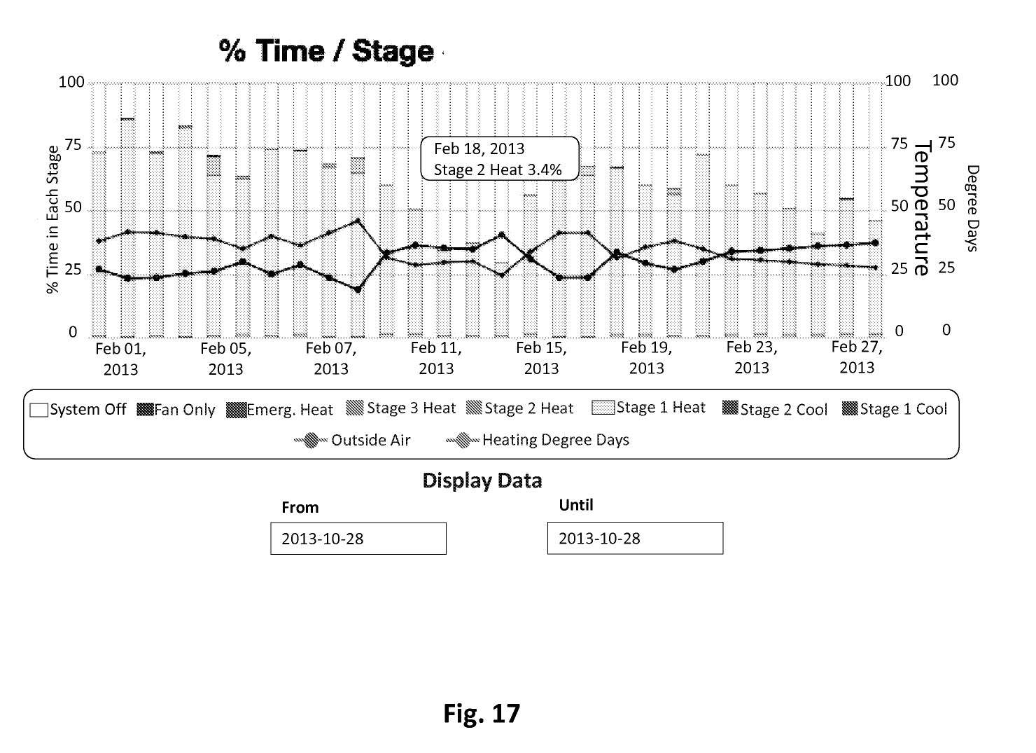

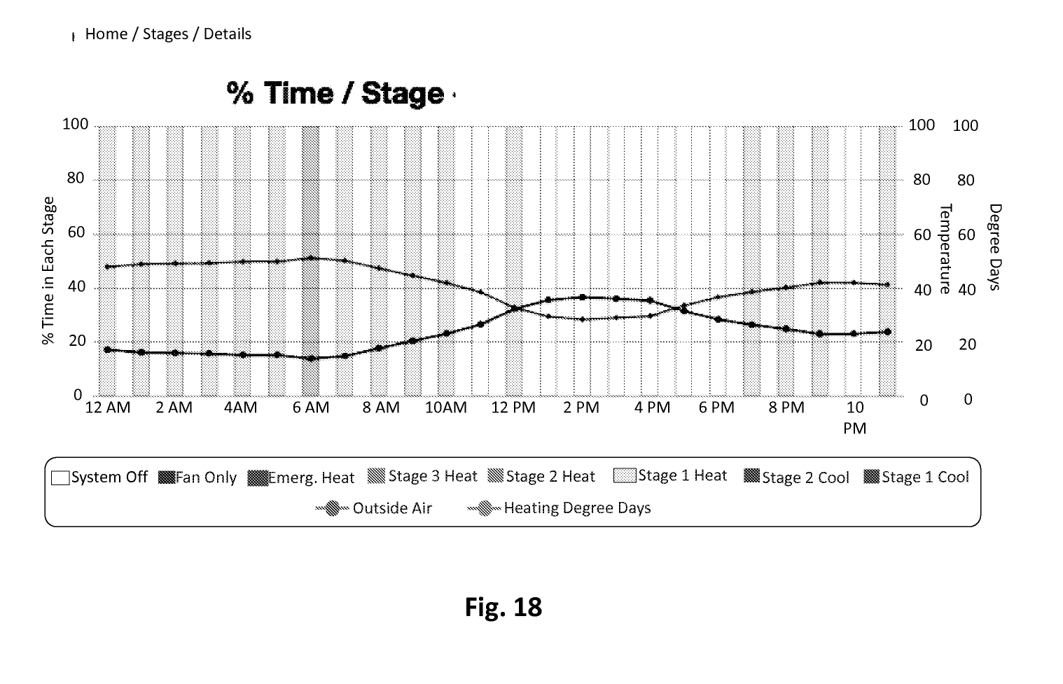

The present invention also provides significant interface advantages with respect to information display. In particular, using simple cursor motions it is possible to expand the period of time over which particular data is viewed. This feature is particularly evident in the comparison of FIGS. 17 and 18. As discussed above, geothermal heating/cooling systems often present themselves as having more than one heating stage. As demands for heating or cooling increase, activation of an additional stage of heating or cooling may be called for by the system. Sometimes second or third stage heating is provided by the heat pump itself operating in a higher power mode. At other times, additional heating/cooling stages are provided by external backup heating or cooling sources. Such sources include electrical resistance heating or a separate fossil fueled heating system. In general, the greater amount of time spent in second or third stage heating, the more costly is the result and there is a decline in overall inefficiency. Accordingly, it is desirable to provide information to a user and/or service personnel concerning the amount of time spent in different heating stages. In order to satisfy this need or desire, the system of the present invention is also capable of providing information such as that shown in FIGS. 17 and 18. This is another example of useful data that is extractable from the database created by the present invention. Additionally, it is to be noted that FIG. 18 shows essentially the same data as presented in FIG. 17 except that the timescale has been more narrowly focused to provide an indication of system performance over a shorter period of time.

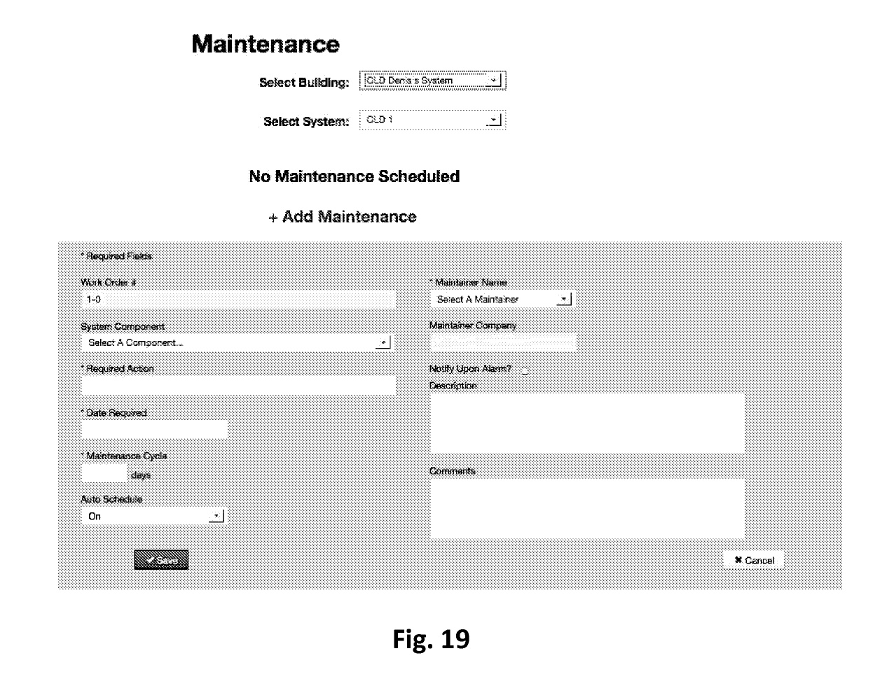

The data used in the day-to-day operation of the present invention is not confined to the kinds of data discussed above. It is should also be noted that the present invention also provides capabilities for associating maintenance information with a particular customer. A computer screen displaying such information is illustrated in FIG. 19. The following information fields are exemplary of such data: work order number; system component; required action; date required; maintenance cycle; automatic scheduling flag; maintainer personnel; maintainer company; alarm notification flag; maintenance description; and a general comments field. This information is stored in the database and is associated with a particular customer and/or with a particular customers unit. It should be borne in mind that any given customer may have on-site a plurality of geothermal systems particularly in the context of commercial installations. Along these lines, it is useful to point out that the present invention should not be understood to be limited to individual homeowner installations. In the case of both individual and commercial installations, it is seen that the present invention provides a capability for establishing and using a maintenance schedule. This is particularly useful with the present invention since system performance information may be determined prior to and/or subsequent to a maintenance visit to ensure that performed maintenance was effective and useful.

Remote monitoring systems of the kind discussed herein can in fact be severely limited by the fact that system changes and modifications cannot easily be incorporated. For example, a homeowner may build an addition to his/her residence thus requiring another thermostat and or another entire heat pump system. Additionally, further sensors may be deployed for determining temperature and/or flow rate in various sets of conduits. A system which cannot accommodate and adjust to these changes has significant reduction in value particularly in terms of the value presented to a geothermal system installer who is tasked with the chore of having to modify a relatively complex installation. Many of these problems are alleviated and/or completely solved by the use of daughter card 560 which provides both a mechanical and electrical interface to the array of geothermal sensors present in a “standard” installation. As another indicator of the flexibility of the present invention consider the observation over one period of time when it was seen that flow rate indications (sensor 275 in FIG. 3) were inaccurate at levels below about one gallon per minute. The present invention permits downloading of software to SBC 390 to account for this and other such observational flukes. This downloading is accomplishable from server 105 (or locally, if need be).

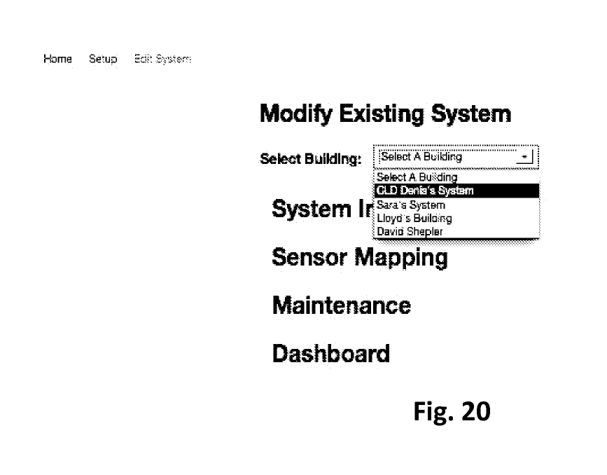

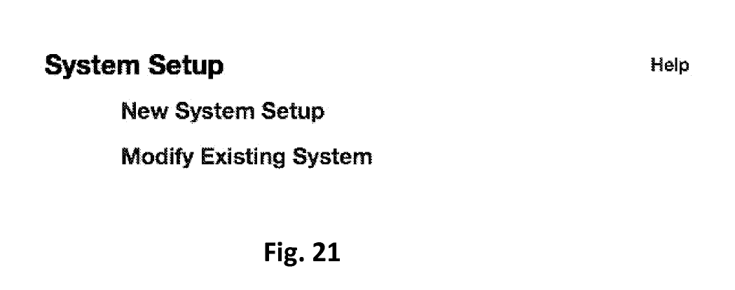

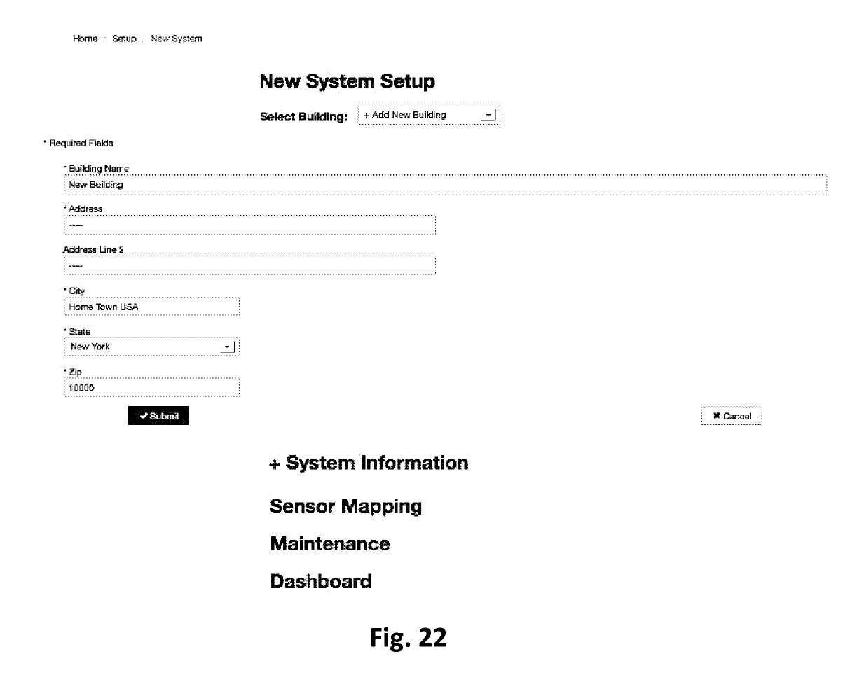

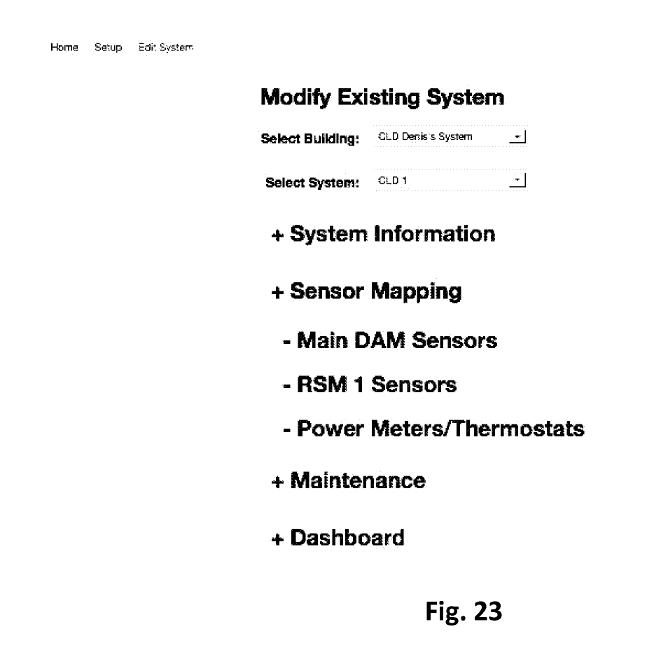

However, the present invention provides significant flexibility in this area. This flexibility begins with system installation in which various computer ports are mapped to different information transducers. In particular, in the present invention this mapping is capable of being carried out, not only locally, but remotely. Thus, in normal system installation this mapping may occur from a remote location after installation of the monitoring system and all of the associated transducers. In the present invention, there is provided a software function which performs the desired mapping. This functionality is illustrated in FIGS. 20 to 24. These figures are “screenshots” of various options presented to a system user. In particular, FIG. 20 illustrates a menu in which sensor mapping is an option. Selection of this option results in the menu illustrated in FIG. 21 where the user chooses between sensor mapping in a new system or sensor mapping in an existing system which is to be modified. The selection of a new system results in presentation of the menu table shown in FIG. 22. The fields shown therein are self-explanatory. If the option is to change sensor mapping for an existing system the menu options presented to the user are shown in FIG. 23. Should the particular sensor mapping to be modified is the one associated with power meters and/or thermostats, the menu options presented are those shown in FIG. 24.

The present invention is thus seen to provide a low cost, interactive, scalable, expandable, remotely configurable energy monitoring and logging system and service, enabling real-time monitoring, control and diagnosis of geothermal heating and cooling systems to support the site owner and service provider with accurate system performance information. The availability of parametric information is seen to be important to maintaining and verifying that the geothermal heating and cooling system is operating as intended.

System efficiency and health is seen to be determined by the collection and correlation of context sensitive analog and digital information from the desired system components. A profile of how these components are performing under varying day-to-day load and demand conditions provides the end user of this information with a practical means for analyzing system performance over time. In addition to monitoring the system for general system performance, a watchdog application is used to provide alert if certain thresholds are exceeded.

All publications and patent applications mentioned in this specification are indicative of the level of skill of those skilled in the art to which this invention pertains. All publications and patent applications are herein incorporated by reference to the same extent as if each individual publication or patent application was specifically and individually indicated to be incorporated by reference.

Although the description above contains many specifics, these should not be construed as limiting the scope of the invention, but as merely providing illustrations of some of the presently preferred embodiments of this invention. Thus, the scope of this invention should be determined by the appended claims and their legal equivalents. Therefore, it will be appreciated that the scope of the present invention fully encompasses other embodiments which may become obvious to those skilled in the art, and that the scope of the present invention is accordingly to be limited by the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 USC §112, sixth paragraph, unless the element is expressly recited using the phrase “means for.”

While the invention has been described in detail herein in accordance with certain preferred embodiments thereof, many modifications and changes therein may be effected by those skilled in the art. Accordingly, it is intended by the appended claims to cover all such modifications and changes as fall within the spirit and scope of the invention.

What is claimed is:

1. A system for monitoring the operational status of a geothermal system, said monitoring system comprising:
transducers for measuring at least temperature difference and flow rate in a geothermal heat energy transfer system;
a microprocessor for polling said transducers and for associating data provided by said transducers with a time at which said polling occurred, and for storing said transducer data and said associated time in local storage;
a computer capable of being remotely configured and capable of receiving said stored data from said microprocessor and capable of transferring said stored data, to a remote location; and
a data processor, at said remote location, for receiving said transferred data.

2. The monitoring system of claim 1 in which said transducers are selected from the group consisting of at least two of the following: a flow meter, a pressure sensor, a temperature sensor, a thermostat, a power meter and a state indicator.

3. The monitoring system of claim 1 in which said microprocessor element further includes a real time clock for providing said time.

4. The monitoring system of claim 3 in which said real time clock further includes a battery back-up.

5. The monitoring system of claim 1 in which said microprocessor element further includes a removal storage device.

6. The monitoring system of claim 1 in which said data processor at said remote location is capable of analyzing said transferred data to generate indicia selected from the group consisting of alerts, performance data, trends, costs and status.

7. A data acquisition module for a geothermal system, said module comprising:
a microprocessor including storage therein for instructions and data;
a real time clock accessible by said microprocessor;
at least three ports for receipt of analog temperature and flow rate information by said microprocessor;
and
non-volatile storage for containment of a database of time-stamp based information received through said ports, said database being generated under control of said instructions.

8. The data acquisition module of claim 7 in which said microprocessor is capable of remotely mapping said ports transducers associated with said geothermal system.

9. A monitoring system for a geothermal heat transfer system, said monitoring system comprising:
a remote processor capable of generating time stamped records indicative of operating parameters of said geothermal heat transfer system;
a central hosting facility, linked to said remote processor and containing a database of said records received from said remote processor; and
a display mechanism which displays a facsimile image of said geothermal heat transfer system along with indicators of said operating parameters as derived from said database.

10. An apparatus for use in a geothermal monitoring system, said apparatus comprising:
a data processing system mounted on a circuit board and capable of collecting, storing and transferring geothermal transducer data to a remote location; and
a distinct connector board connectable to said circuit board on which said data processing system is mounted and having conductors thereon for connection to data transducers employable in a geothermal system.
